(19) United States
(12) Patent Application Publication
(10) Pub. No.: US 2018/0261464 A1
(43) Pub. Date: Sep. 13, 2018

(54) OXIDE FILM REMOVING METHOD, OXIDE FILM REMOVING APPARATUS, CONTACT FORMING METHOD, AND CONTACT FORMING SYSTEM

(71) Applicant: Tokyo Electron Limited, Tokyo (JP)

(72) Inventors: Takashi Kobayashi, Yamanashi (JP); Takashi Sakuma, Yamanashi (JP); Hideaki Yamasaki, Yamanashi (JP); Rio Shimizu, Yamanashi (JP); Einosuke Tsuda, Yamanashi (JP)

(21) Appl. No.: 15/914,071

(22) Filed: Mar. 7, 2018

(30) Foreign Application Priority Data
Mar. 8, 2017 (JP) 2017-043853
Jul. 18, 2017 (JP) 2017-138968

(51) Int. Cl. H01L 21/311; H01L 21/02; H01L 29/66; H01L 21/67; H01L 21/285; H01L 21/677; H01L 29/45

(52) U.S. Cl. CPC H01L 21/31116; H01L 21/02063; H01L 29/66795; H01L 29/456; H01L 21/28518; H01L 21/67739; H01L 21/67167; H01L 21/67069

(57) ABSTRACT

Disclosed is a method for removing, from a processing target substrate having an insulating film with a predetermined pattern formed thereon, a silicon-containing oxide film formed in a silicon portion of a bottom of the pattern. The method includes: removing the silicon-containing oxide film formed on the bottom of the pattern by ionic anisotropic plasma etching using plasma of a carbon-based gas; removing a remaining portion of the silicon-containing oxide film after the anisotropic plasma etching, by chemical etching; and removing a residue remaining after the chemical etching.

### CROSS-REFERENCE TO RELATED APPLICATIONS

This application is based on and claims priority from Japanese Patent Application Nos. 2017-043853 and 2017-138968 filed on Mar. 8, 2017 and Jul. 18, 2017, respectively, with the Japan Patent Office, the disclosures of which are incorporated herein in their entirety by reference.

### TECHNICAL FIELD

The present disclosure relates to an oxide film removing method, an oxide film removing apparatus, a contact forming method, and a contact forming system.

### BACKGROUND

In a case of forming a contact made of silicide on a silicon surface of the bottom of a pattern (e.g., a contact hole or a trench), it is necessary to remove any natural oxide film formed on the silicon surface. Thus, anisotropic etching by ionic etching has been known as a technique for removing the natural oxide film on the bottom of the pattern (see, e.g., Japanese Patent Laid-Open Publication No. 2003-324108).

Meanwhile, for example, in a fin-type channel field effect transistor (fin FET) which is a three-dimensional device, a fin channel having a plurality of Si fins is formed on the bottom of a fine trench formed in an insulating film (SiO₂ film and SiN film), and a Ti film, for example, is formed as a contact metal on the source and drain portions thereof. Thus, a contact is formed. The source and drain portions of the fin-type channel are formed by epitaxially growing Si or SiGe on the Si fins. From the viewpoint of improving the contact performance, a step of removing a natural oxide film (SiO₂ film) formed on the surface of the source and drain portions is performed before forming the contact metal.

The anisotropic etching by ionic etching has also been used as a technique for removing the natural oxide film of the source and drain of the fin FET.

Further, since the structure of the source and drain portions of the fin FET is complicated, a chemical oxide removal (COR) processing is considered as a processing capable of removing the natural oxide film in a portion where ions hardly reach. The COR processing is a processing of removing an oxide film by plasmaless dry etching using HF gas and NH₃ gas, and is described in, for example, International Publication No. WO 2007/049510.

### SUMMARY

According to a first aspect, the present disclosure provides a method for removing, from a processing target substrate having an insulating film with a predetermined pattern formed thereon, a silicon-containing oxide film formed in a silicon portion of a bottom of the pattern. The method includes: removing the silicon-containing oxide film formed on the bottom of the pattern by ionic anisotropic plasma etching using plasma of a carbon-based gas; removing a remaining portion of the silicon-containing oxide film after the anisotropic plasma etching, by chemical etching; and removing a residue remaining after the chemical etching.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a flowchart illustrating an oxide film removing method according to a first exemplary embodiment.

FIGS. 2A to 2D are sectional views illustrating the oxide film removing method according to the first exemplary embodiment step by step.

FIG. 3 is a sectional view, taken along a direction orthogonal to a trench, illustrating a structure for forming a fin FET to which the oxide film removing method according to the first exemplary embodiment is applied.

FIG. 4 is a sectional view, taken along a direction of the trench, illustrating a structure for forming the fin FET to which the oxide film removing method according to the first exemplary embodiment is applied.

FIG. 5 is a flowchart illustrating another example of the oxide film removing method according to the first exemplary embodiment.

FIGS. 6A and 6B are sectional views illustrating a part of the steps in FIG. 5.

FIG. 7 is a flowchart illustrating an example of a contact forming method including the oxide film removing method according to the first exemplary embodiment.

FIGS. 8A to 8C are sectional views illustrating an example of the contact forming method including the oxide film removing method according to the first exemplary embodiment step by step.

FIG. 9 is a sectional view illustrating an exemplary oxide film removing apparatus.

FIG. 10 is a horizontal sectional view schematically illustrating a contact forming system including the oxide film removing apparatus.

FIG. 11 is a flowchart illustrating an oxide film removing method according to a second exemplary embodiment.

FIGS. 12A to 12D are sectional views illustrating the oxide film removing method according to the second exemplary embodiment step by step.

FIGS. 13A to 13D are views for explaining a mechanism of the oxide film removing method according to the second exemplary embodiment.

FIG. 14 is a graph illustrating results of measurement of a residual carbon concentration in a test example of the second exemplary embodiment with respect to a case where etching with C₄F₈ gas was performed on a Si substrate (sample 1), a case where O₂ ashing was performed on a Si substrate after etching with C₄F₈ gas (sample 2), a case where H₂ ashing was performed on a Si substrate after etching with C₄F₈ gas (sample 3), and a case where an O₂ flow+H₂ plasma processing was performed on a Si substrate according to the second exemplary embodiment after etching with C₄F₈ gas (sample 4).

FIG. 15 is a graph illustrating results of measurement of a residual oxygen concentration for samples 1 to 4 in FIG. 14.

FIG. 16 is a graph illustrating a change in residual carbon concentration with respect to a plasma time for sample 4, a case of H₂ ashing at 200 W, and a case of H₂ ashing at 500 W in the test example of the second exemplary embodiment.

FIG. 17 is a graph illustrating specific resistance of a contact when a natural oxide film of the Si substrate is removed and then Ti is deposited by plasma CVD to form a TiSi contact, in the test example of the second exemplary embodiment. The natural oxide film removal was performed in three manners, that is, only by the COR processing with NH₃ gas and HF gas (reference), by performing the O₂ flow+H₂ plasma processing according to the second exemplary embodiment under the same conditions as in sample 4 and then performing the COR processing (sample 5), and by performing the H₂ ashing after etching with C₄F₈, and then performing the COR processing (sample 6).

FIG. 18 illustrates SEM (TEM) photographs of cross-sections of the reference, sample 5, and sample 6 in FIG. 17.

FIG. 19 is a graph illustrating the results of measurement of an oxygen concentration in the vicinity of the interface between the Ti film and the Si substrate by performing SIMS measurement, in the reference, sample 5, and sample 6 in FIG. 17.

FIG. 20 illustrates TEM photographs of cross-sections of an initial state before removing a natural oxide film on the bottom of the trench formed in the insulating film on the Si substrate, a case where a natural oxide film on the bottom of the trench formed in the insulating film on the Si substrate is removed by COR and then a Ti film is formed to form a TiSi contact (sample 7), and a case where a C₄F₈ etching-O₂ flow-H₂ plasma processing is performed according to the second exemplary embodiment and then a Ti film is formed to form a TiSi contact (sample 8), in the test example of the second exemplary embodiment.

FIG. 21 is a flowchart illustrating an oxide film removing method according to a third exemplary embodiment.

FIGS. 22A to 22C are sectional views illustrating the oxide film removing method according to the third exemplary embodiment step by step.

FIG. 23 is a graph illustrating the results of measurement of a residual carbon concentration in a test example of the third exemplary embodiment with respect to a case where etching with C₄F₈ gas was performed on a Si substrate (sample 1 in the second exemplary embodiment) and a case where an O₂ ashing+H₂ plasma processing was performed on a Si substrate after etching with C₄F₈ gas (sample 4) as comparative examples, and a case where a H₂/N₂ plasma processing was performed on a Si substrate after etching with C₄F₈ gas (sample 11).

FIG. 24 is a graph illustrating the results of measurement of a residual oxygen concentration for samples 1, 4, and 11 in FIG. 23.

FIG. 25 is a graph illustrating a change in residual carbon concentration with respect to plasma time for sample 11, a case of H₂ ashing at 200 W, and a case of H₂ ashing at 500 W in the test example of the third exemplary embodiment.

FIG. 26 is a graph illustrating specific resistance of a contact when a natural oxide film of the Si substrate is removed and then Ti is deposited by plasma CVD to form a TiSi contact, in the test example of the third exemplary embodiment. The natural oxide film removal was performed in three manners, that is, only by the COR processing with NH₃ gas and HF gas (reference), by performing the H₂/N₂ plasma processing according to the second exemplary embodiment under the same conditions as in sample 11 and then performing the COR processing (sample 12), and by performing the H₂ ashing after etching with C₄F₈, and then performing the COR processing (sample 6 in the second exemplary embodiment).

FIG. 27 illustrates SEM photographs of cross-sections of the reference, sample 12, and sample 6 in FIG. 26.

FIG. 28 is a graph illustrating the results of measurement of an oxygen concentration in the vicinity of the interface between the Ti film and the Si substrate by performing SIMS measurement, in the reference, sample 12, sample 6 in FIG. 26.

FIG. 29 illustrates TEM photographs of cross-sections of an initial state before removing a natural oxide film on the bottom of the trench formed in the insulating film on the Si substrate, a case where a natural oxide film on the bottom of the trench formed in the insulating film on the Si substrate is removed by COR and then a Ti film is formed to form a TiSi contact (sample 7 in the second exemplary embodiment), and a case where a C₄F₈ etching-H₂/N₂ plasma processing is performed according to the third exemplary embodiment and then a Ti film is formed to form a TiSi contact (sample 13), in the test example of the third exemplary embodiment.

FIG. 30 is a schematic view illustrating a state where a carbon-containing layer is formed when ionic anisotropic etching is performed using plasma of a carbon-containing gas.

FIG. 31 is a diagram illustrating the relationship between the processing time of the H₂/N₂ plasma processing and the carbon amount.

FIG. 32 is a flowchart illustrating an oxide film removing method according to a fourth exemplary embodiment.

FIGS. 33A to 33E are sectional views illustrating the oxide film removing method according to the fourth exemplary embodiment step by step.

FIG. 34 is a graph illustrating the results of measurement of a residual carbon concentration in the test example of the third exemplary embodiment with respect to a case where only the COR processing is performed (sample 21), a case where H₂/N₂ plasma processing is performed after etching with C₄F₈ gas (sample 22), and a case where O₂ ashing is performed after etching with C₄F₈ gas (sample 23).

FIG. 35 is a graph illustrating the relationship between the processing time of the O₂ plasma processing and the oxide film thickness in the test example of the fourth exemplary embodiment.

FIG. 36 is a flowchart illustrating an oxide film removing method according to a fifth exemplary embodiment.

FIGS. 37A to 37C are sectional views illustrating the oxide film removing method according to the fifth exemplary embodiment step by step.

FIG. 38 is a graph illustrating the relationship between the ashing time and the residual carbon concentration measured by XPS with respect to sample 31 (the third exemplary embodiment), sample 32 (“high” NH₃ flow rate ratio), sample 33 (“medium” NH₃ flow rate ratio), and sample 34 (“low” NH₃ flow rate ratio), in the test example of the fifth exemplary embodiment.

FIG. 39 is a graph illustrating the relationship between the ashing time and the residual fluorine concentration measured by XPS with respect to sample 31 (the third exemplary embodiment), sample 32 (“high” NH₃ flow rate ratio), sample 33 (“medium” NH₃ flow rate ratio), and sample 34 (“low” NH₃ flow rate ratio), in the test example of the fifth exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The COR processing is an isotropic processing. Thus, when the COR processing is used for removing a natural oxide film on the bottom of a trench, an insulating film on the side walls of the trench is also etched, resulting in critical dimension (CD) loss. With recent device miniaturization, the width of the insulating film between trenches is required to be smaller than 10 nm. When the insulating film on the side walls of the trench is etched and CD loss occurs, leakage problems may arise. Therefore, it is necessary to suppress the CD loss as much as possible. Further, as the device miniaturization further progresses, the influence of CD loss may not be ignored even when anisotropic etching by ionic etching is used.

Accordingly, an object of the present disclosure is to provide a technique capable of suppressing CD loss when removing a silicon-containing oxide film formed on a silicon portion of the bottom of a pattern such as a trench, and a technique of forming a contact on the bottom of the pattern from which an oxide film is removed using the technique.

According to a first aspect, the present disclosure provides a method for removing, from a processing target substrate having an insulating film with a predetermined pattern formed thereon, a silicon-containing oxide film formed in a silicon portion of a bottom of the pattern. The method includes: removing the silicon-containing oxide film formed on the bottom of the pattern by ionic anisotropic plasma etching using plasma of a carbon-based gas; removing a remaining portion of the silicon-containing oxide film after the anisotropic plasma etching, by chemical etching; and removing a residue remaining after the chemical etching.

In the method according to the first aspect, the silicon-containing oxide film on the bottom of the pattern may be a natural oxide film formed on a surface of the silicon portion of the bottom of the pattern.

Further, the processing target substrate may be a substrate for forming a fin FET and have a silicon fin and an epitaxial growth portion made of Si or SiGe formed at a tip portion of the silicon fin, and the epitaxial growth portion may constitute the silicon portion.

The removing the residue may be performed by a H₂-containing plasma processing using plasma of a H₂-containing gas.

The method further includes removing a carbon-based protective film remaining on a side wall of the pattern after the anisotropic plasma etching. The removing the residue may be performed to remove a reaction product generated by the chemical etching.

In this case, the removing the carbon-based protective film may be performed by a H₂-containing plasma processing using plasma of a H₂-containing gas. In this case, the removing the carbon-based protective film may be performed by the H₂-containing plasma processing after an O₂-containing gas is supplied to the processing target substrate, a H₂/N₂ plasma processing using plasma of H₂ gas and N₂ gas, or a H₂/NH₃ plasma processing using plasma of H₂ gas and NH₃ gas. Further, the removing the carbon-based protective film may be performed by an O₂ gas plasma processing.

The anisotropic plasma etching may be performed by plasma of a fluorocarbon-based gas or a fluorinated hydrocarbon-based gas. The anisotropic plasma etching may be performed at a pressure of 0.1 Torr or less. The chemical etching may be performed by a gas processing using NH₃ gas and HF gas.

The insulating film may include a SiO₂ film. Further, the respective steps of the method may be performed at substantially the same temperature in a range of 10° C. to 150° C., and preferably 20° C. to 60° C. Further, the respective steps of the method may be performed continuously in a single processing container.

According to a second aspect, the present disclosure provides a method for removing, from a processing target substrate having an insulating film with a predetermined pattern formed thereon, a silicon-containing oxide film formed in a silicon portion of a bottom of the pattern. The method includes: removing the silicon-containing oxide film formed on the bottom of the pattern by ionic anisotropic plasma etching using plasma of a carbon-based gas; and removing a carbon-based protective film remaining on a side wall of the pattern after the anisotropic plasma etching. The removing the carbon-based protective film is performed by a H₂-containing plasma processing is performed using plasma of a H₂-containing gas after an O₂-containing gas is supplied to the processing target substrate.

In the method according to the second aspect, the O₂-containing gas may be supplied at a flow rate of 10 sccm to 5,000 sccm and a time of 0.1 sec to 120 sec. The flow rate may be 100 sccm to 1,000 sccm, and the time may be 1 sec to 10 sec. Further, the H₂-containing plasma processing may be performed with a pressure of 0.02 Torr to 0.5 Torr, an H₂ gas flow rate of 10 sccm to 5,000 sccm, an RF power of 10 W to 1,000 W, and a time of 1 sec to 120 sec. The pressure may be 0.05 Torr to 0.3 Torr, the H₂ gas flow rate may be 100 sccm to 1,000 sccm, the RF power may be 100 W to 500 W, and the time may be 5 sec to 90 sec. Further, the O₂-containing gas flow+H₂-containing plasma processing may be performed once, but even when the total processing time is the same, the O₂-containing gas flow+H₂-containing plasma processing may be divided into several sub-steps and performed a plurality of times, for example, in three cycles.

According to a third aspect, the present disclosure provides a method for removing, from a processing target substrate having an insulating film with a predetermined pattern formed thereon, a silicon-containing oxide film formed in a silicon portion of a bottom of the pattern. The method includes: removing the silicon-containing oxide film formed on the bottom of the pattern by ionic anisotropic plasma etching using plasma of a carbon-based gas; and removing a carbon-based protective film remaining on a side wall of the pattern after the anisotropic plasma etching. The removing the carbon-based protective film is performed by a H₂/N₂ plasma processing using plasma of H₂ gas and N₂ gas.

In the method according to the third aspect, the H₂/N₂ plasma processing is performed with a pressure of 0.02 Torr to 0.5 Torr, an H₂ gas flow rate of 10 sccm to 5,000 sccm, an N₂ gas flow rate of 5 sccm to 5,000 sccm, an RF power of 10 W to 1,000 W, and a time of 1 sec to 120 sec. The pressure may be 0.05 Torr to 0.3 Torr, the H₂ gas flow rate may be 100 sccm to 1,000 sccm, the N₂ gas flow rate may be 10 sccm to 1,000 sccm, the RF power may be 100 W to 500 W, and the time may be 10 sec to 90 sec.

According to a fourth aspect, the present disclosure provides a method for removing, from a processing target substrate having an insulating film with a predetermined pattern formed thereon, a silicon-containing oxide film formed in a silicon portion of a bottom of the pattern. The method includes: removing the silicon-containing oxide film formed on the bottom of the pattern by ionic anisotropic plasma etching using plasma of a carbon-based gas; and removing a carbon-based protective film remaining on a side wall of the pattern after the anisotropic plasma etching. The removing the carbon-based protective film is performed by a H₂/NH₃ plasma processing using plasma of H₂ gas and NH₃ gas.

In the method according to the fourth aspect, the H₂/NH₃ plasma processing is performed with a pressure of 0.1 Torr to 1.0 Torr, an H₂ gas flow rate of 10 sccm to 5,000 sccm, an NH₃ gas flow rate of 1 sccm to 1,000 sccm, an RF power of 10 W to 1,000 W, and a time of 1 sec to 150 sec. The pressure may be 0.3 Torr to 0.7 Torr, an H₂ gas flow rate of 100 sccm to 700 sccm, an NH₃ gas flow rate of 5 sccm to 500 sccm, an RF power of 50 W to 500 W, and a time of 10 sec to 120 sec. A flow rate ratio of NH₃ gas to H₂ gas+NH₃ gas in the H₂/NH₃ plasma processing may be in a range of 0.1% to 25%.

According to a fifth aspect, the present disclosure provides an apparatus for removing, from a processing target substrate having an insulating film with a predetermined pattern formed thereon, a silicon-containing oxide film formed in a silicon portion of a bottom of the pattern. The apparatus includes: a processing container that accommodates the processing target substrate; a processing gas supply mechanism that supplies a predetermined processing gas into the processing container; an exhaust mechanism that exhausts an atmosphere in the processing container; a plasma generating mechanism that generates plasma in the processing container; and a controller that controls the processing gas supply mechanism, the exhaust mechanism, and the plasma generating mechanism. The controller controls the processing gas supply mechanism, the exhaust mechanism, and the plasma generating mechanism to perform the above-described method.

According to a sixth aspect, the present disclosure provides a contact forming method including: removing, from a processing target substrate having an insulating film with a predetermined pattern formed thereon, a silicon-containing oxide film formed in a silicon portion of a bottom of the pattern by the above-described method; forming a metal film after the silicon-containing oxide film is removed; and forming a contact on the bottom of the pattern by reacting the silicon portion with the metal film.

The forming the metal film may be performed by CVD or ALD.

According to a seventh aspect, the present disclosure provides a contact forming system that removes, from a processing target substrate having an insulating film with a predetermined pattern formed thereon, a silicon-containing oxide film formed in a silicon portion of a bottom of the pattern, and forms a contact in the silicon portion. The contact forming system includes: the above-described apparatus that removes the silicon-containing film of the processing target substrate; a metal film forming apparatus that forms a metal film after the silicon-containing oxide film is removed; a vacuum conveyance chamber to which the oxide film removing apparatus and the metal film forming apparatus are connected; and a conveyance mechanism provided in the vacuum conveyance chamber.

The metal film forming apparatus may form the metal film by CVD or ALD.

According to a eighth aspect, the present disclosure provides a non-transitory computer-readable storage medium that stores a computer program for controlling an oxide film removing apparatus which, when executed, causes a computer to control the oxide film removing apparatus and execute the above-described method.

According to a ninth aspect, the present disclosure provides a non-transitory computer-readable storage medium that stores a computer program for controlling a contact forming system which, when executed, causes a computer to control the contact forming system and execute the above-described contact forming method.

According to the present disclosure, after the silicon-containing oxide film formed in the silicon portion of the bottom of the pattern is removed by ionic anisotropic plasma etching with plasma of a carbon-based gas, a remaining portion of the silicon-containing oxide film is removed by chemical etching, and then a residue remaining after the chemical etching is removed. Therefore, it is possible to suppress the CD loss when removing the silicon-containing oxide film formed in the silicon portion of the bottom of the pattern.

Hereinafter, exemplary embodiments of the present disclosure will be described in detail with reference to the drawings.

### First Exemplary Embodiment

[Oxide Film Removing Method]

First, an oxide film removing method according to a first exemplary embodiment will be described.

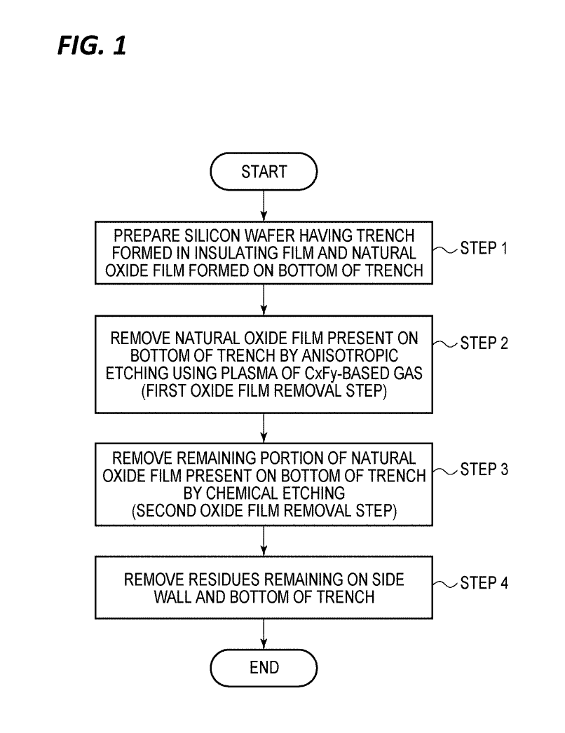

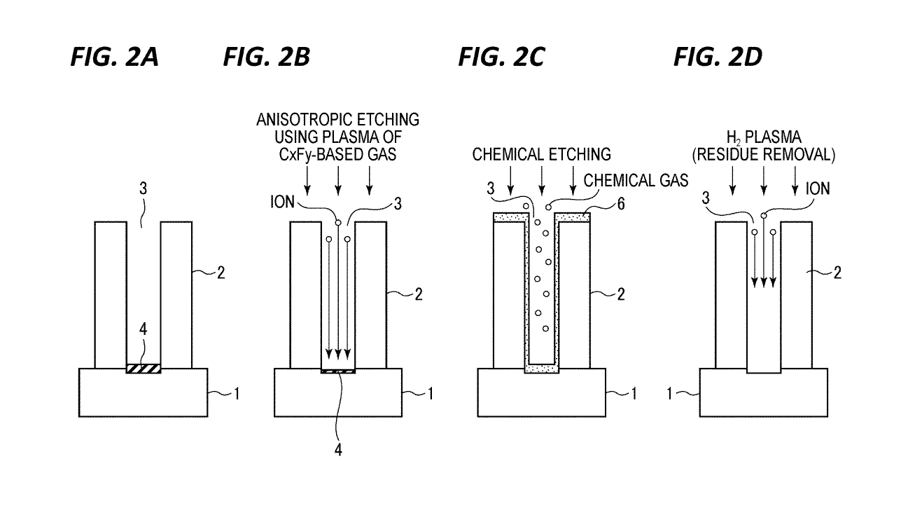

FIG. 1 is a flowchart illustrating an oxide film removing method according to a first exemplary embodiment. FIGS. 2A to 2D are sectional views illustrating the oxide film removing method step by step.

In the exemplary embodiment, descriptions will be made on a case of removing a natural oxide film formed on the surface of a silicon portion of the bottom of a trench formed as a predetermined pattern in a workpiece before forming a contact by depositing a contact metal on the silicon portion.

First, a processing target substrate (silicon wafer) having an insulating film 2 formed on a silicon base 1 and a trench 3 formed as a predetermined pattern in the insulating film 2 is prepared (step 1; FIG. 2A). A natural oxide film (silicon-containing oxide film) 4 is formed on the silicon portion of the bottom of the trench 3. The insulating film 2 is mainly made of a SiO₂ film. A part of the film may be a SiN film.

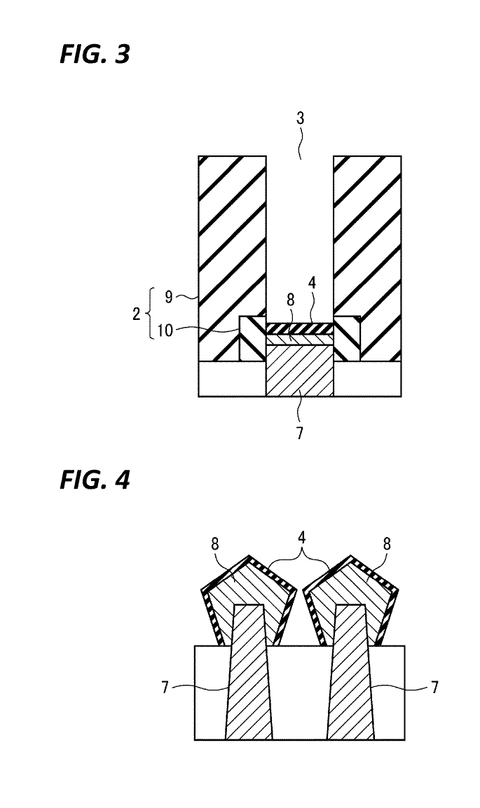

The processing target substrate (silicon wafer) may be, for example, a substrate for forming a fin FET. FIGS. 3 and 4 are sectional views illustrating an example of the processing target substrate for forming a fin FET. FIG. 3 is a sectional view taken along a direction orthogonal to the trench 3, and FIG. 4 is a sectional view taken along the direction of the trench 3. In this example, the processing target substrate has a polygonal epitaxial growth portion 8 made of Si or SiGe formed at a tip portion of a Si fin 7, on the bottom of the trench 3. The epitaxial growth portion 8 constitutes a source and a drain. In addition, the natural oxide film 4 is formed on the surface of the epitaxial growth portion 8. In this example, the insulating film 2 is made of a SiO₂ film 9 which is a main portion, and a SiN film 10 which constitutes a bottom portion. In FIG. 4, epitaxial growth portions 8 are illustrated as having a pentagonal shape, but may have a tetragonal shape.

The trench of the fin FET has, for example, a top CD of 8 nm to 10 nm, a depth of 100 nm to 120 nm, and an aspect ratio of 12 to 15.

Prior to the oxide film removing processing, a cleaning processing (e.g., a pre-clean processing) may be performed on a workpiece (silicon wafer).

Next, the natural oxide film 4 on the bottom of the trench is removed by ionic anisotropic etching with plasma of a carbon-containing gas (first oxide film removal step) (step 2; FIG. 2B).

This step is an anisotropic etching utilizing rectilinearity of ions, and a fluorocarbon-based (CₓF_{y}-based) gas (e.g., CF₄ or C₄F₈) may be suitably used as the carbon-containing gas. Further, a fluorinated hydrocarbon-based (CₓH_{y}F_{z}-based) gas (e.g., CH₂F₂) may also be used. Further, in addition to these, a rare gas (e.g., Ar gas), an inert gas (e.g., N₂ gas), and even a slight amount of O₂ gas may be contained.

When these gases are used, a carbon-based protective film is formed on the side walls of the trench 3 during the anisotropic etching. Thus, it is possible to etch the natural oxide film while suppressing the etching progress of the side walls. As a result, it is possible to remove most of the natural oxide film 4 on the bottom of the trench while suppressing the CD loss.

When the anisotropic etching is performed in step 2, the pressure may be as low as possible, and is set to about 0.1 Torr (13.3 Pa) or less in order to ensure the rectilinearity of ions. Further, since it is a plasma processing, the temperature may be low, and strict temperature control is unnecessary, but the temperature may be the same as that of the subsequent step 3.

The carbon-based protective film formed on the side walls in step 2 may or may not be removed after step 2.

Most of the natural oxide film 4 is removed by the first oxide film removal step in step 2, but the natural oxide film on the surface of the epitaxial growth portion 8 having a complicated shape on the bottom of the trench of the fin FET illustrated in FIG. 4 may not be removed by anisotropic etching alone.

Therefore, after the first oxide film removal step in step 2, the remaining portion of the natural oxide film 4 present on the bottom of the trench 3 is removed by chemical etching (second oxide film removal step) (step 3; FIG. 2C).

Since the chemical etching is plasmaless and dry etching with a reactive gas and isotropic etching, the natural oxide film 4 on the surface of the epitaxial growth portion 8 having a complicated shape may be removed. The COR processing using NH₃ gas and HF gas is suitable for the chemical processing.

In the COR processing, an inert gas (e.g., Ar gas or N₂ gas) may be added as a diluent gas in addition to NH₃ gas and HF gas.

Since chemical etching such as the COR processing is isotropic etching, there is a concern that the side walls of the trench is also etched, resulting in CD loss. In step 3, however, since only the natural oxide film slightly remaining on the bottom of the trench is removed, a short-time processing is sufficient, and almost no CD loss occurs in practice. Further, when the carbon-based protective film on the side walls of the trench is not removed, the carbon-based protective film is not reactive to the NH₃ gas and the HF gas. Thus, it is possible to further suppress etching of the side walls of the trench.

When step 3 is performed, the processing pressure may be about 0.01 Torr to 5 Torr (1.33 Pa to 667 Pa). Further, the temperature may be set in a range of about 10° C. to 150° C., and within the range, a lower temperature of 20° C. to 60° C. is preferable. When the processing is performed at such a low temperature, it is possible to enhance the smoothness of the etched surface.

After the COR processing, when the carbon-based protective film is removed, a reaction product mainly containing ammonium fluorosilicate ((NH₄)₂SiF₆; AFS) is formed on the upper surface of the insulating film 2 and the bottom of the trench 3 by reaction with NH₃ gas and HF gas. At this time, some reaction products are also formed on the side walls. Further, in the case where the carbon-based protective film is not removed in advance, the reaction product is generated only on the upper surface of the insulating film 2 and the bottom of the trench 3, and the carbon-based protective film remains on the side walls, so that no reaction product is generated.

Therefore, since the residue 6, which contains only the reaction product or the reaction product and the carbon-based protective film, remains on the upper surface of the insulating film 2, the residue 6 remaining on the side walls and the bottom of the trench 3 is then removed (step 4; FIG. 2D).

When the temperature of step 3 is high to a certain extent, a part of AFS which is a reaction product is vaporized and removed during the processing of step 3.

The residue removal processing in step 4 is performed by, for example, H₂ plasma which is plasma of a H₂-containing gas. As a result, it is possible to remove the residue 6 while suppressing re-oxidation of the side walls and the bottom portion.

In the case of using H₂ plasma in step 4, since the removal processing is performed by plasma, it is desirable that the processing pressure is set to be somewhat low. However, since it is necessary to remove the residue on the side walls, it is desirable that the rectilinearity is weaker than that in step 2. Therefore, the processing pressure in step 4 may be higher than that in step 2 and may be about 0.5 Torr (66.7 Pa) or less. Further, since it is a plasma processing, it can be performed at a low temperature, which may be the same temperature as the temperature of step 3.

However, when the carbon-based protective film on the side walls of the trench and the reaction product after the chemical etching are removed at the same time, the processing time may become long and the removal may not be sufficient.

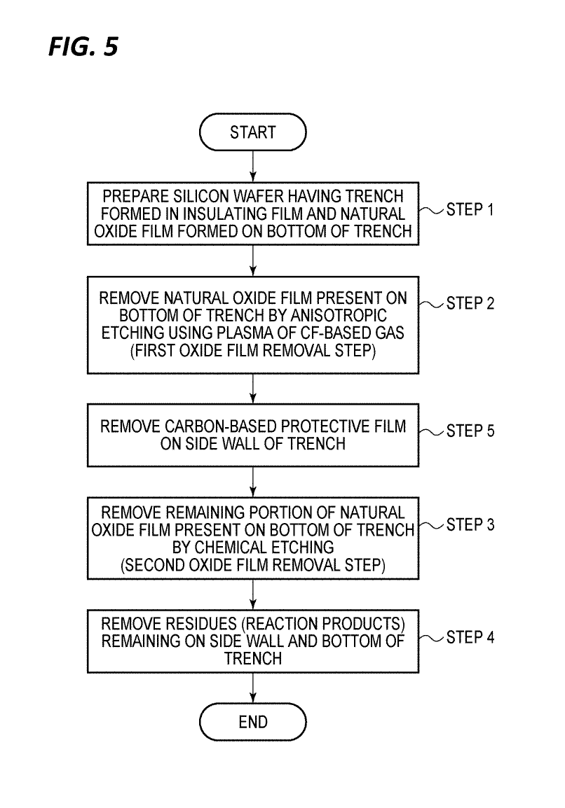

Therefore, as illustrated in FIG. 5, a carbon-based protective film removal processing (step 5) may be performed immediately after the first oxide film removal step in step 2, so that only AFS, which is a reaction product, is removed in step 4.

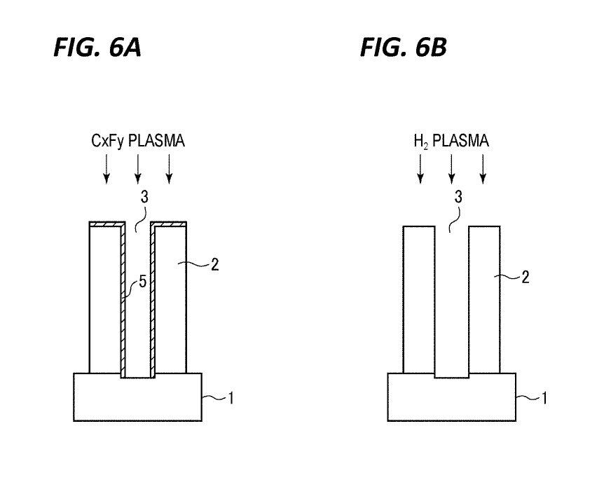

Specifically, as illustrated in FIG. 6A, after step 2 is performed, the carbon-based protective film 5 remains on the upper surface and the side walls of the trench 3. Thus, as illustrated in FIG. 6B, the carbon-based protective film 5 may be removed by H₂ plasma in step 5, for example, in the same manner as in step 4. The conditions at this time may be set to be substantially the same as in step 4.

As described above, first, in the first oxide film removal step, the natural oxide film (SiO₂ film) 4 on the bottom of the trench 3 is removed by anisotropic etching using a carbon-based gas. Thus, etching may be performed while forming a carbon-based protective film on the side walls of the trench. Therefore, it is possible to remove most of the natural oxide film 4 on the bottom of the trench 3 while suppressing the CD loss due to etching of the side walls by the carbon-based protective film formed at the time of etching, without adding additional steps such, for example, as carbon film formation. Further, the natural oxide film 4 that is unable to be removed by anisotropic etching is removed by isotropic chemical etching in the second oxide film removal step. However, since the remaining natural oxide film 4 is little, a short processing time is sufficient, and the CD loss is small. Therefore, it is possible to remove the natural oxide film on the bottom of the trench 3 while suppressing the CD loss without complicated steps.

Therefore, in the case where the source and the drain, which are the semiconductor portions on the bottom of the trench 3, have complicated shapes like the structure for forming the fin FET, it is possible to remove the natural oxide film while suppressing the CD loss.

Further, since steps 2 to 4 or steps 2, 5, and 3 to 4 may be performed at substantially the same temperature, the natural oxide film removal processing may be performed in a short time, and the throughput may be kept high. Further, since these steps are all gas processings and are able to be performed at the same temperature, it is possible to perform the processings in the same chamber, so that the natural oxide film removal processing may be performed in a shorter time.

[Contact Forming Method]

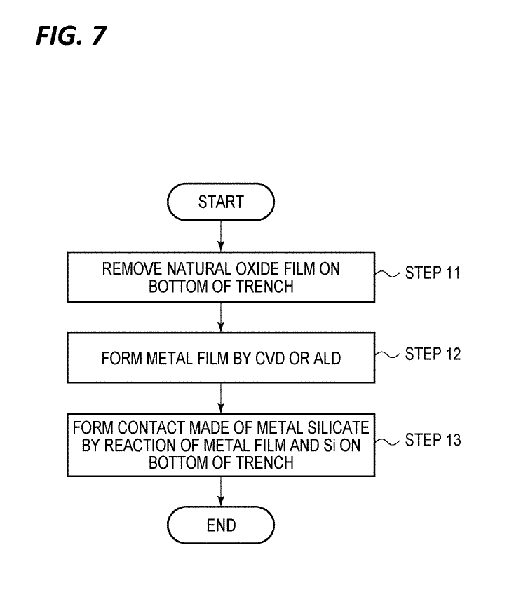

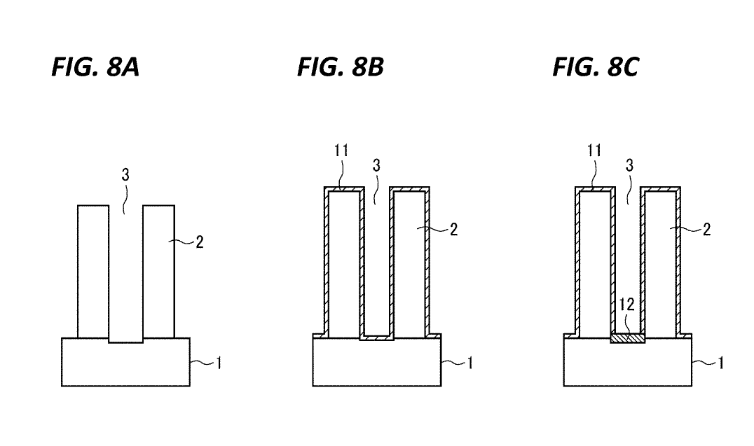

Next, an exemplary embodiment of a contact forming method after the oxide film removal processing will be described with reference to the flowchart of FIG. 7 and the process sectional views of FIGS. 8A to 8C.

Here, by steps 1 to 4 or the process of adding step 5, which is the carbon-based protective film removal step, to steps 1 to 4, the natural oxide film on the bottom of the trench 3 is removed as illustrated in FIG. 8A (step 11), and then, a metal film 11 is formed as a contact metal by CVD or ALD as illustrated in FIG. 8B (step 12). Examples of the metal film include a Ti film, a Ta film.

Then, as illustrated in FIG. 8C, the metal film 11 reacts with silicon on the bottom of the trench 3 so that a contact 12 made of metal silicate (e.g., TiSi) is formed in a self-aligning manner (step 13).

[Oxide Film Removing Method]

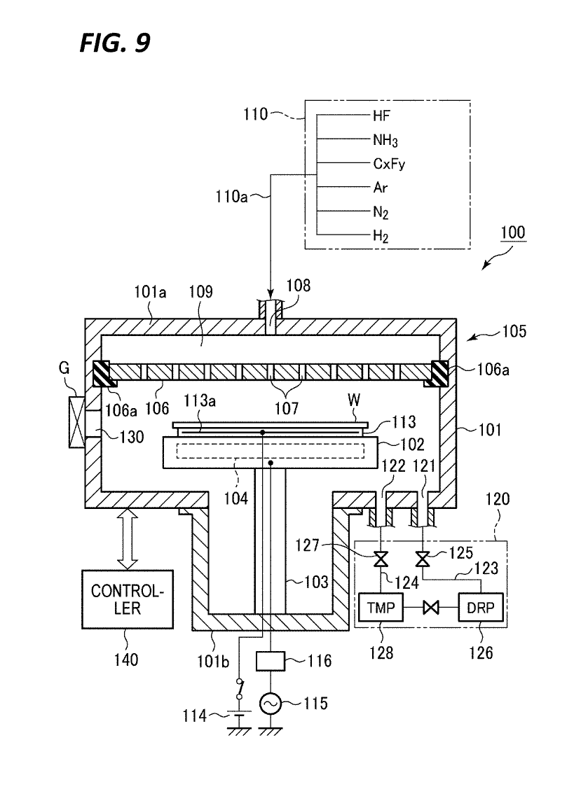

Next, an example of an oxide film removing apparatus used for performing the oxide film removing method according to the first exemplary embodiment will be described. FIG. 9 is a sectional view illustrating an exemplary oxide film removing apparatus.

The oxide film removing apparatus 100 includes a substantially cylindrical chamber (processing container) 101. The inner wall surface of the chamber 101 is made of, for example, aluminum on which a surface treatment was not performed, or aluminum on which an out gas-free (OGF) anodic oxidation treatment was performed.

A susceptor 102 is provided inside the chamber 101 in a state of being supported by a cylindrical support member 103 provided in the lower central portion to horizontally support a silicon wafer (target substrate) W which is a structure in which the structure illustrated in FIG. 2A is formed on the entire surface. Although not illustrated, the susceptor 102 is insulated from the support member 103 and the chamber 101. An opening is formed in the center of the bottom portion of the chamber 101, and a cylindrical protruding portion 101b is connected to the lower portion of the opening portion. The support member 103 is supported by the bottom portion of the protruding portion 101b.

For example, the main body of the susceptor 102 is made of aluminum, and an insulating ring (not illustrated) is formed on the outer periphery thereof. A temperature adjustment mechanism 104 is provided inside the susceptor 102 to adjust the temperature of the silicon wafer W thereon. For example, the temperature adjustment mechanism 104 adjusts the temperature of the silicon wafer W to a proper temperature required for the processing in a range of, for example, 10° C. to 150° C. by allowing the temperature-controlled temperature adjustment medium to flow through a flow path formed in the susceptor 102.

Three lift pins (not illustrated) for conveying the silicon wafer W are provided in the susceptor 102 so as to protrude and retract from the surface of the susceptor 102. An electrostatic chuck 113 is provided on the upper surface of the susceptor 102 to electrostatically attract the silicon wafer W. The electrostatic chuck 113 has a structure in which an electrode 113a is provided inside a dielectric such as alumina, and when a high voltage is applied from a high voltage DC power supply 114 to the electrode 113a, the silicon wafer W is attracted to the upper surface of the electrostatic chuck 113 by an electrostatic attraction force such as Coulomb force. Since the silicon wafer W is attracted by the electrostatic chuck 113, it is possible to control the temperature of the silicon wafer W with high precision by the temperature adjustment mechanism 104.

A shower head 105 is provided in the upper portion of the chamber 101. The shower head 105 has a shower plate 106 having a disc shape and provided with a plurality of gas ejection holes 107, which are provided right under a top wall 101a of the chamber 101. The shower plate 106 used herein may be, for example, one in which a thermal spray coating made of yttria is formed on the surface of the main body made of aluminum. The shower plate 106 and the chamber 101 are insulated by a ring-shaped insulating member 106a. The insulating member 106a may be replaced with a conductive material such that all of the outer frame of the shower head 105, the chamber 101, the shower plate 106, and the member 106a are electrically connected.

A gas introduction port 108 is provided at the center of the top wall 101a of the chamber 101, and a gas diffusion space 109 is defined between the top wall 101a and the shower plate 106.

The gas introduction port 108 is connected with a gas pipe 110a of a gas supply mechanism 110. Then, the gas supplied from the gas supply mechanism 110 (to be described later) is introduced from the gas introduction port 108, is diffused into the gas diffusion space 109, and is ejected into the chamber 101 from the gas discharge holes 107 of the shower plate 106.

The gas supply mechanism 110 includes a plurality of gas supply sources that individually supply HF gas, NH₃ gas, a CₓF_{y} gas (carbon-containing gas), Ar gas, N₂ gas, and H₂ gas, and a plurality of gas supply pipes that supply respective gases from the plurality of gas supply sources (all not illustrated). Each gas supply pipe is provided with an opening/closing valve and a flow rate controller (e.g., a mass flow controller) (all of which are not illustrated), which make it possible to appropriately switch the gases and control the flow rate of each gas. The gases from the gas supply pipes are supplied to the shower head 105 via the gas pipe 110a described above.

Meanwhile, a high frequency power supply 115 is connected to the susceptor 102 via a matcher 116, and high frequency power is applied to the susceptor 102 from the high frequency power supply 115. The susceptor 102 functions as a lower electrode, and the shower plate 106 functions as an upper electrode, thereby constituting a pair of parallel plate electrodes. When high frequency power is applied to the susceptor 102, capacitively coupled plasma is generated in the chamber 101. Further, when high frequency power is applied from the high frequency power supply 115 to the susceptor 102, ions in the plasma are drawn into the silicon wafer W. The frequency of the high frequency power output from the high frequency power supply 115 may be set to 0.1 MHz to 500 MHz, for example, 13.56 MHz.

An exhaust mechanism 120 is provided in the bottom portion of the chamber 101. The exhaust mechanism 120 includes a first exhaust pipe 123 and a second exhaust pipe 124 provided in respective exhaust ports 121 and 122 formed in the bottom portion of the chamber 101, a first pressure control valve 125 and a dry pump 126 provided in the first exhaust pipe 123, and a second pressure control valve 127 and a turbo pump 128 provided in the second exhaust pipe 124. Further, during the film formation processing in which the inside of the chamber 101 is set to a high pressure, the dry pump 126 alone exhausts the gas, and during the plasma processing in which the inside of the chamber 101 is set to a low pressure, the dry pump 126 and the turbo pump 128 are used in combination. The pressure control in the chamber 101 is performed by controlling the opening degree of the pressure control valves 125 and 127 based on the detection value of a pressure sensor (not illustrated) provided in the chamber 101.

The side wall of the chamber 101 is provided with a carry-in/out port 130 through which the silicon wafer W is carried into/out from a vacuum conveyance chamber (not illustrated) to which the chamber 101 is connected, and a gate valve G that opens and closes the carry-in/out port 130. The conveyance of the silicon wafer W is performed by a conveyance mechanism (not illustrated) provided in the vacuum conveyance chamber.

The oxide film removing apparatus 100 includes a controller 140. The controller 140 includes a main controller having a CPU (computer) that controls respective components of the oxide film removing apparatus 100, for example, a valve or a mass flow controller of the gas supply mechanism, the high frequency power source 115, the exhaust mechanism 120, the temperature adjustment mechanism 104, the conveyance mechanism, and the gate valve G, an input device (e.g., a keyboard and a mouse), an output device (e.g., a printer), a display device (e.g., a display), and a storage device (e.g., a storage medium). The main controller of the controller 140 causes the oxide film removing apparatus 100 to execute a predetermined operation based on a processing recipe stored in the storage medium built in the storage device or a storage medium set in the storage device.

Next, the processing operation of the oxide film removing apparatus configured as described above will be described. The following processing operation is executed based on the processing recipe stored in the storage medium in the controller 140.

First, the gate valve G is opened, and a silicon wafer W, which is a structure in which the structure illustrated in FIG. 2A is formed on the entire surface, is carried out from a vacuum conveyance chamber (not illustrated) via a carry-in/out port 130 by a conveyance mechanism (not illustrated) and placed on the susceptor 102. In this state, the conveyance mechanism is retreated from the chamber 101, and the gate valve G is closed.

Next, the pressure in the chamber 101 is adjusted to a low pressure 1 Torr (13.3 Pa) or less by the exhaust mechanism 120. At this time, in addition to the CₓF_{y} gas, Ar gas or N₂ gas may be added. In order to adjust the pressure in the chamber 101 to the lower pressure, the exhaust in the chamber 101 is performed using the turbo pump 128 in addition to the dry pump 126. The temperature of the silicon wafer W is maintained at 10° C. to 150° C., preferably 20° C. to 60° C. by the temperature adjustment mechanism 104. The temperature at this time is set to the temperature at the time of the second oxide film removal step by chemical etching which requires a strict temperature control to be performed later. Further, the high voltage DC power supply 114 is turned on, so that the silicon wafer W is electrostatically attracted by the electrostatic chuck 113.

In this state, plasma is generated by turning on the high frequency power supply 115 while supplying the CₓF_{y} gas which is a carbon-containing gas (e.g., C₄F₈ gas) from the gas supply mechanism 110 into the chamber 101 via the shower head 105 at a predetermined flow rate, and the first oxide film removal step is performed by anisotropic etching with CₓF_{y} ions to remove most of the natural oxide film on the bottom of the trench. At this time, since the carbon-based protective film is formed on the side walls of the trench by the CₓF_{y}-based gas, the natural oxide film on the bottom of the trench may be removed while suppressing the CD loss.

After the first oxide film removal step, the inside of the chamber 101 is purged with Ar gas or N₂ gas while being exhausted by the exhaust mechanism 120.

After the purge is completed, the carbon-based protective film may be removed. In order to remove the carbon-based protective film, the pressure in the chamber 101 is adjusted by the exhaust mechanism 120 to a predetermined pressure that is higher than the first oxide film removal step and equal to or lower than 0.5 Torr (66.7 Pa) while maintaining the silicon wafer W at the same temperature. Then, the high frequency power supply 115 is turned on while supplying, for example, H₂ gas, or H₂ gas and N₂ gas from the gas supply mechanism 110 into the chamber 101 via the shower head 105 at predetermined flow rates. At this time, the exhaust in the chamber 101 is also performed using the turbo pump 128 in addition to the dry pump 126. Therefore, for example, the carbon-based protective film on the side walls of the trench is removed by H₂ plasma and H₂/N₂ plasma.

After the carbon-based protective film removal processing, the inside of the chamber 101 is purged with Ar gas or N₂ gas while being exhausted by the exhaust mechanism 120.

After the purge is completed, the pressure in the chamber 101 is adjusted to a predetermined pressure within a range of 0.01 Torr to 5 Torr (1.33 Pa to 667 Pa) by the exhaust mechanism 120 while maintaining the silicon wafer W at the same temperature, and NH₃ gas and HF gas are supplied from the gas supply mechanism 110 into the chamber 101 via the shower head 105 at predetermined flow rates. Then, the second oxide film removal processing by reaction of these gases is performed to remove the remaining portion of the natural oxide film. At least one of the N₂ gas and the Ar gas may be supplied as a dilution gas together with the NH₃ gas and the HF gas. At this time, since the pressure in the chamber 101 may be used in a range from a relatively low pressure to a relatively high pressure, it is possible to exhaust with a combination of the turbo pump 128 and the dry pump 126, or with the dry pump 126 alone.

Since the etching at this time is a gas processing without plasma, it is isotropic and it is possible to remove the natural oxide film remaining in the complicated-shaped silicon region which is unable to be removed in the first oxide film removal step. The etching at this time is isotropic, but it is sufficient to remove a slightly remaining natural oxide film. Thus, the CD loss is hardly generated.

After the etching processing of the natural oxide film, the inside of the chamber 101 is purged with N₂ gas or Ar gas while being exhausted by the exhaust mechanism 120.

After the purge is completed, the pressure in the chamber 101 is adjusted to 5 Torr (667 Pa) or less by the dry pump 126 and the turbo pump 128 of the exhaust mechanism 120 while maintaining the silicon wafer W at the same temperature, and the high frequency power supply 115 is turned on while supplying H₂ gas, or H₂ gas and N₂ gas from the gas supply mechanism 110 into the chamber 101 via the shower head 105 at predetermined flow rates. Then, H₂ plasma or H₂/N₂ plasma is performed to remove a residue. The residue at this time is AFS which is a reaction product generated in the second oxide film removal step in the case where the carbon-based protective film is removed in advance. In the case where the carbon-based protective film is not removed, the residue includes a carbon-based protective film and AFS.

After the residue removal processing, the inside of the chamber 101 is purged with Ar gas or N₂ gas, and the gate valve G is opened so that the silicon wafer W on the susceptor 102 is carried out by the conveyance mechanism.

By a series of the processings described above, it is possible to securely remove the natural oxide film on the bottom of the trench while suppressing the CD loss.

In addition, since the series of processings described above is performed continuously in the chamber 101, the processings may be performed with high efficiency. Further, since the series of processings is performed at the same temperature, the processing time may be shortened, and high throughput may be obtained.

[Contact Forming System]

Next, descriptions will be made on a contact forming system including the oxide film removing apparatus 100.

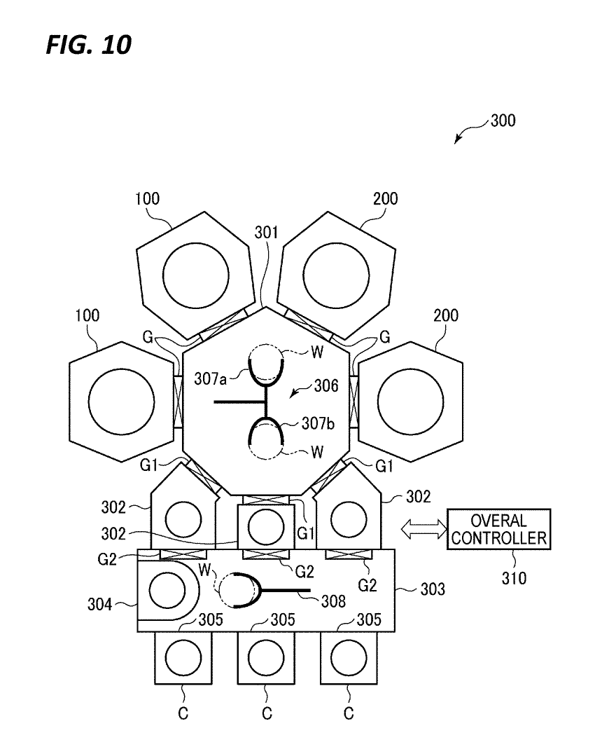

FIG. 10 is a horizontal sectional view schematically illustrating a contact forming system.

The contact forming system 300 performs the oxide film removal processing described above, and then forms a contact by forming, for example, a Ti film as a contact metal.

As illustrated in FIG. 10, the contact forming system 300 includes two oxide film removing apparatuses 100 and two metal film forming apparatuses 200. These are connected to four wall portions of a vacuum conveyance chamber 301 having a heptagonal planar shape via the gate valves G, respectively. The inside of the vacuum conveyance chamber 301 is evacuated by a vacuum pump and maintained at a predetermined degree of vacuum. That is, the contact forming system 300 is a multi-chamber type vacuum processing system and may continuously perform the above-described contact formation without breaking the vacuum.

The oxide film removing apparatus 100 is configured as described above. The metal film forming apparatus is, for example, an apparatus for forming a metal film, for example, a Ti film, a Ta film, a Co film, or a Ni film on a silicon wafer W by CVD or ALD within a chamber in a vacuum atmosphere.

In addition, three load lock chambers 302 are connected to the other three wall portions of the vacuum conveyance chamber 301 via gate valves G1. An atmospheric conveyance chamber 303 is provided at the opposite side of the vacuum conveyance chamber 301 across the load lock chambers 302. The three load lock chambers 302 are connected to the atmospheric conveyance chamber 303 via the gate valves G2. The load lock chamber 302 controls the pressure between the atmospheric pressure and the vacuum when the silicon wafer W is conveyed between the atmospheric conveyance chamber 303 and the vacuum conveyance chamber 301.

In the wall of the atmospheric conveyance chamber 303 on the side opposite to the load lock chamber 302 mounting wall portion, three carrier mounting ports 305 are provided to mount a carrier (e.g., a FOUP) C that accommodates a wafer W. In addition, an alignment chamber 304 is provided on a side wall of the atmospheric conveyance chamber 303 to align the silicon wafer W. A downflow of clean air is formed in the atmospheric conveyance chamber 303.

A conveyance mechanism 306 is provided in the vacuum conveyance chamber 301. The conveyance mechanism 306 conveys the silicon wafer W to the oxide film removing apparatuses 100, the metal film forming apparatuses 200, and the load lock chambers 302. The conveyance mechanism 306 includes two conveyance arms 307a and 307b that are movable independently.

A conveyance mechanism 308 is provided in the atmospheric conveyance chamber 303. The conveyance mechanism 308 is configured to convey the silicon wafer W to the carriers C, the load lock chambers 302, and the alignment chamber 304.

The contact forming system 300 includes an overall controller 310. The overall controller 310 includes a main controller having a CPU (computer) that controls, for example, the respective components of the oxide film removing apparatus 100 and the metal film forming apparatus 200, the exhaust mechanism, the gas supply mechanism, or the conveyance mechanism 306 of the vacuum conveyance chamber 301, the exhaust mechanism or the gas supply mechanism of the load lock chamber 302, the conveyance mechanism 308 of the atmospheric conveyance chamber 303, and the driving mechanism of the gate valves G, G1, G2, an input device (e.g., a keyboard and a mouse), an output device (e.g., a printer), a display device (e.g., a display), and a storage device (e.g., a storage medium). The main controller of the overall controller 310 causes the contact forming system 300 to execute a predetermined operation based on a processing recipe stored in the storage medium built in the storage device or a storage medium set in the storage device. The overall controller 310 may be a high-ranking controller of the controller of each unit such as the controller 140.

Next, the processing operation of the contact forming apparatus configured as described above will be described. The following processing operation is executed based on the processing recipe stored in the storage medium in the overall controller 310.

First, the silicon wafer W is taken out from the carrier C connected to the atmospheric conveyance chamber 303 by the conveyance mechanism 308 and passes through the alignment chamber 304, and the gate valve G2 of any one of the load lock chambers 302 is opened such that the silicon wafer W is carried into that load lock chamber 302. The gate valve G2 is closed, and then the inside of the load lock chamber 302 is evacuated.

When the load lock chamber 302 reaches a predetermined degree of vacuum, the gate valve G1 is opened to take out the silicon wafer W from the load lock chamber 302 by one of the conveyance arms 307a and 307b of the conveyance mechanism 306.

Then, the gate valve G of any one of the oxide film removing apparatuses 100 is opened, and the silicon wafer W held by any of the conveyance arms of the conveyance mechanism 306 is carried into the oxide film removing apparatus 100. The empty conveyance arm is returned to the vacuum conveyance chamber 301, and the gate valve G is closed. Then, the oxide film removing processing is performed by the oxide film removing apparatus 100.

After the oxide film removal processing is completed, the gate valve G of the oxide film removing apparatus 100 is opened, and the silicon wafer W therein is carried out by one of the conveyance arms 307a and 307b of the conveyance mechanism 306. Then, the gate valve G of any one of the metal film forming apparatuses 200 is opened, and the silicon wafer W held by the conveyance arm is carried into the metal film forming apparatus 200. The empty conveyance arm is returned to the vacuum conveyance chamber 301, and the gate valve G is closed. Then, a metal film to be a contact metal (e.g., a Ti film, a Ta film, a Co film, or a Ni film) is formed by the metal film forming apparatus 200 by CVD or ALD. At this time, the metal film reacts with silicon on the bottom of the trench to form a contact made of a metal silicate (e.g., TiSi).

After the formation of the metal film and the contact formation, the gate valve G of the metal film forming apparatus 200 is opened, and the silicon wafer W therein is carried out by one of the conveyance arms 307a and 307b of the conveyance mechanism 306. Then, the gate valve G1 of one of the load lock chambers 302 is opened, and the silicon wafer W on the conveyance arm is carried into the load lock chamber 302. Then, the inside of the load lock chamber 302 is returned to the atmosphere. The gate valve G2 is opened, and the silicon wafer W in the load lock chamber 302 is returned to the carrier C by the transfer mechanism 308.

The above processing is performed on a plurality of silicon wafers W concurrently in parallel, and the contact forming processing for a predetermined number of silicon wafers W is completed.

As described above, the oxide film removing apparatus 100 may perform a series of oxide film removal processings with high efficiency in one chamber. Thus, when the contact forming system 300 is formed by mounting two oxide film removing apparatuses 100 and two metal film forming apparatuses 200, it is possible to achieve oxide film removal and contact formation by metal film formation with high throughput. In addition, since a series of these processings may be performed without breaking the vacuum, it is possible to suppress oxidation in the course of the processings.

### Second Exemplary Embodiment

Next, an oxide film removing method according to a second exemplary embodiment will be described.

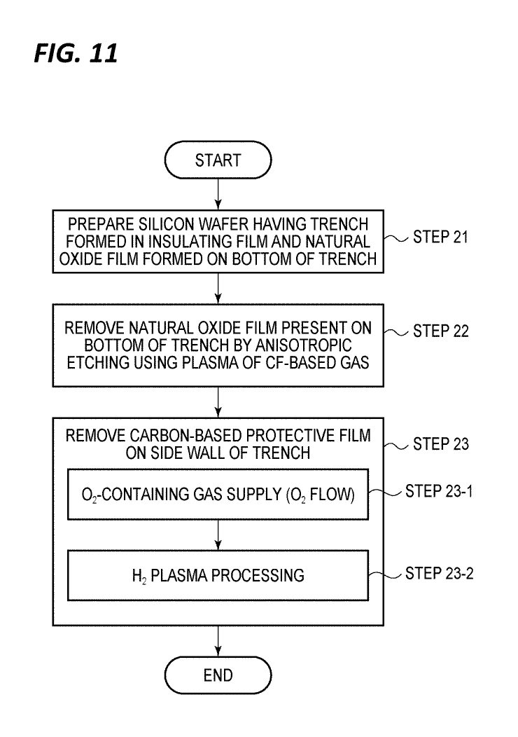

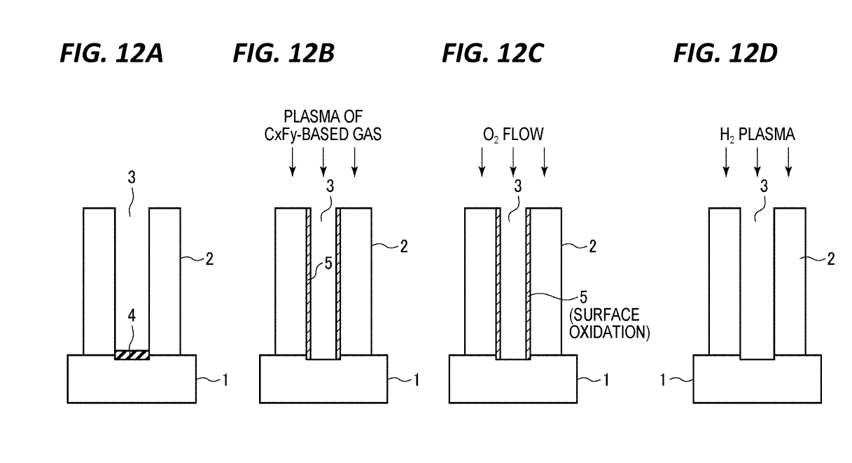

FIG. 11 is a flowchart illustrating an oxide film removing method according to a second exemplary embodiment. FIGS. 12A to 12D are sectional views illustrating the oxide film removing method step by step.

Also in the exemplary embodiment, descriptions will be made on a case of removing a natural oxide film formed on the surface of a silicon portion of the bottom of a trench formed as a predetermined pattern in a workpiece before forming a contact by depositing a contact metal on the silicon portion.

First, a processing target substrate (silicon wafer) having an insulating film 2 formed on a silicon base 1 and a trench 3 formed as a predetermined pattern in the insulating film 2 is prepared (step 21; FIG. 12A). A natural oxide film (silicon-containing oxide film) 4 is formed on the silicon portion on the bottom of the trench 3. The insulating film 2 is mainly made of a SiO₂ film. A part of the film may be a SiN film.

Prior to the oxide film removing processing, a cleaning processing (e.g., a pre-clean processing) may be performed on a workpiece (silicon wafer).

Next, the natural oxide film 4 on the bottom of the trench is removed by ionic anisotropic etching with plasma of a carbon-containing gas (step 22; FIG. 12B).

As in step 2 in the first exemplary embodiment, a fluorocarbon-based (CₓF_{y}-based) gas (e.g., CF₄ or C₄F₈) may be suitably used as the carbon-containing gas. Further, a fluorinated hydrocarbon-based (CₓH_{y}F_{z}-based) gas (e.g., CH₂F₂) may also be used. Further, in addition to these, a rare gas (e.g., Ar gas), an inert gas (e.g., N₂ gas), and even a slight amount of O₂ gas may be contained.

When these gases are used, a carbon-based protective film is formed on the side walls of the trench 3 during the anisotropic etching. Thus, it is possible to etch the natural oxide film while suppressing the etching progress of the side walls.

As in step 2 in the first exemplary embodiment, the pressure in the anisotropic etching in the step 22 may be set to be as low as possible, preferably about 0.1 Torr (13.3 Pa) or less in order to secure the rectilinearity of ions.

Next, the carbon-based protective film on the side walls of the trench is removed (step 23).

It is known that the carbon-based gas as in the present exemplary embodiment is used for plasma etching, and a carbon-based protective film is formed on the side walls when a pattern (e.g., a trench or a contact hole) is formed by the carbon-based gas. In addition, a technique for removing such a carbon-based protective film is also known.

For example, Japanese Patent Laid-Open Publication No. 2003-059911 discloses that a polymer layer (carbon-based protective film) is formed on, for example, a side wall of a pattern and the polymer layer is removed by ashing using oxygen gas or a gas containing oxygen as a main component.

However, when this technique is applied after the natural oxide film 4 is removed as in the present exemplary embodiment, the base silicon may be re-oxidized.

Therefore, in the first exemplary embodiment, H₂ ashing using H₂ plasma by H₂-containing gas plasma is used for removal of the carbon-based protective film, so that the polymer layer is removed and re-oxidation of silicon is suppressed at the same time.

However, in the case of using H₂ plasma, the removal processing with power that does not damage the base will take a long time. Further, when the power is increased to perform the removal in a short time, the base will be damaged. For this reason, it is required to remove the carbon-based protective film in a short time without oxidizing the base and damaging the base with low power.

Accordingly, in this exemplary embodiment, step 23 of removing the carbon-based protective film is performed in two steps, that is, an O₂-containing gas supply (02 flow) step (step 23-1; FIG. 12C) and a H₂ plasma processing step (step 23-2; FIG. 12D). Therefore, the carbon-based protective film may be removed in a short time without damaging the base.

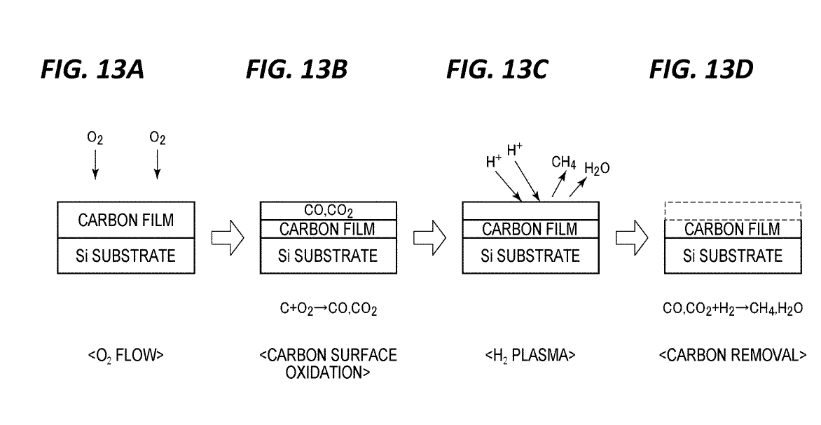

The mechanism at this time will be described with reference to FIGS. 13A to 13D.

When an O₂-containing gas is supplied onto the carbon film as illustrated in FIG. 13A, the O₂-containing gas is adsorbed on the surface of the carbon film to form C—O, and C—O—O bonds by the following formula (1) as illustrated in FIG. 13B. In this state, H₂ plasma is generated as illustrated in FIG. 13C, so that the oxygen adsorption layer or oxide layer on the surface is rapidly removed by the following equation (2) as illustrated in FIG. 13D. In addition, the remaining carbon film is removed by the same reaction formula. Therefore, since the carbon film may be removed in a short time without damaging the base and the oxygen-containing plasma is not used, re-oxidation of the base is unlikely to occur.

C+O₂→CO,CO₂ (1)

CO,CO₂+H₂→CH₄,H₂O (2)

The conditions for the O₂-containing gas supply step of step 23-1 are as follows: pressure: 0.02 Torr to 0.5 Torr (2.67 Pa to 66.7 Pa), O₂ gas flow rate: 10 sccm to 5,000 sccm, and time: 0.1 sec to 60 sec. The pressure may be 0.05 Torr to 0.3 Torr (6.67 Pa to 40.0 Pa), the O₂ gas flow rate may be 100 sccm to 1,000 sccm, and the time may be 1 sec to 10 sec. Further, the conditions for the H₂-containing gas supply step of step 23-2 are as follows: pressure: 0.02 Torr to 0.5 Torr (2.67 Pa to 66.7 Pa), H₂ gas flow rate: 10 sccm to 5,000 sccm, RF power: 10 W to 1,000 W, and time: 0.1 sec to 120 sec. The pressure may be 0.05 Torr to 0.3 Torr (6.67 Pa to 40.0 Pa), the H₂ gas flow rate may be 100 sccm to 1,000 sccm, the RF power may be 100 W to 500 W, and the time may be 5 sec to 90 sec.

In the case where the natural oxide film is removed only by the natural oxide film removal step in step 22, the process is terminated at step 23. Further, in the case where the bottom of the trench 3 has a complicated shape like the processing target substrate for forming the fin FET, after step 23 is completed, isotropic etching by chemical etching (step 3 of the first exemplary embodiment) and residue removal, for example, removal of AFS which is a reaction product (step 4 of first exemplary embodiment) are performed as in the first exemplary embodiment.

Then, after the natural oxide film is removed as described above, a contact made of silicate may be formed by steps 12 to 13 illustrated in FIGS. 7 and 8A to 8C.

Also in the case of this exemplary embodiment, a series of processings may be performed in the same chamber using an oxide film removing apparatus with an O₂ gas line added to the apparatus in FIG. 9. Furthermore, when such an oxide film removing apparatus is installed in the multi-chamber type contact forming system illustrated in FIG. 10, a contact made of silicate may be formed with high throughput while suppressing oxidation.

[Test Result in Second Exemplary Embodiment]

Next, test results in the second exemplary embodiment will be described.

First, a residual carbon concentration and a residual oxygen concentration were measured by XPS in a case where etching with C₄F₈ gas was performed on a Si substrate (bare silicon wafer) (sample 1), a case where a processing with O₂ plasma (O₂ ashing) was performed on a Si substrate (bare silicon wafer) after etching with C₄F₈ gas (sample 2), a case where a processing with H₂ plasma (H₂ ashing) was performed on a Si substrate (bare silicon wafer) after etching with C₄F₈ gas (sample 3), and a case where an O₂ flow+H₂ plasma processing according to the exemplary embodiment was performed on a Si substrate (bare silicon wafer) after etching with C₄F₈ gas (sample 4).

For the conditions of sample 4, the following O₂ flow step and H₂ plasma step were repeated three times.
O₂ flow step
Pressure: 0.1 Torr
O₂ gas flow rate: 500 sccm
Time: 5 sec (pressure adjustment step: 10 sec)
H₂ plasma processing step
Pressure: 0.1 Torr
H₂ gas flow rate: 485 sccm
RF power: 200 W
Time: 10 sec

The H₂ ashing of sample 3 was performed in the same manner as the H₂ plasma processing of sample 4. Further, the O₂ ashing of sample 2 was performed by another apparatus under conditions including 0.1 Torr, O₂ gas flow rate: 500 sccm, RF power: 100 MHz/13.56 MHz=500/100 W.

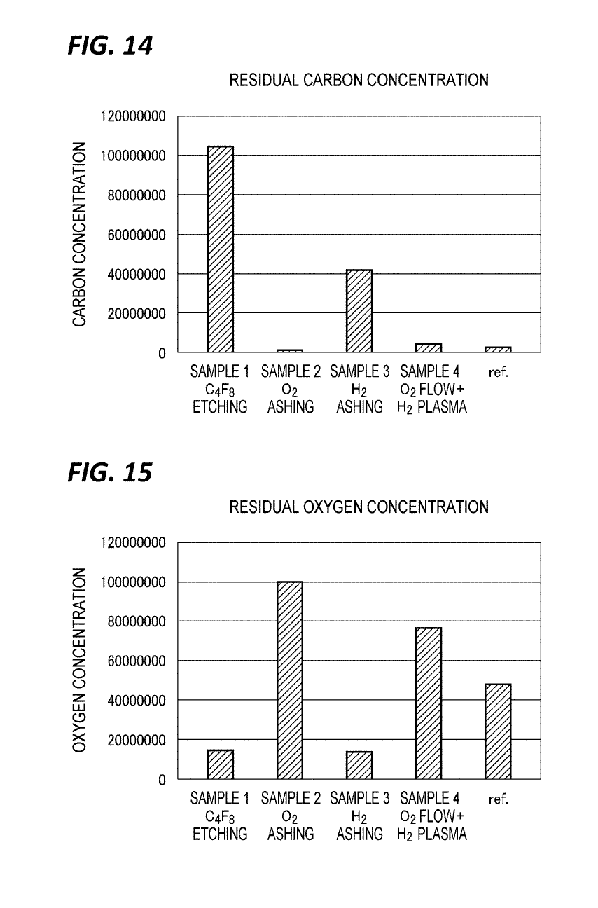

FIG. 14 illustrates the residual carbon concentrations of these samples, and FIG. 15 illustrates the residual oxygen concentrations of these samples. The reference (ref.) represents a value of the silicon substrate (bare silicon).

As illustrated in these figures, in the case of sample 2, on which the O₂ ashing was performed, the residual carbon concentration is low but the residual oxygen concentration is high, and in the case of sample 3, on which the H₂ ashing was performed, the residual oxygen concentration is low but the residual carbon concentration is increased. Meanwhile, it has been found that sample 4, on which the O₂ flow+H₂ plasma processing according to the present exemplary embodiment was performed had a residual oxygen concentration and a low residual carbon concentration lower than those of the sample 2.

When the H₂ ashing time was prolonged to 180 sec, it was possible to obtain the same residual carbon concentration as that of sample 4. However, in this case, the value of the surface roughness (average value) was 0.0478 ppm at the initial, whereas it was increased markedly to 24.2 ppm, causing damage to the base. Further, when the power at the time of H₂ ashing was increased to 500 W, it was possible to lower the residual carbon concentration in a shorter time. However, the surface roughness also deteriorated in this case as well. Meanwhile, in sample 4 of the present exemplary embodiment, the surface roughness was 0.0522 ppm compared with the initial surface roughness of 0.0535 ppm, and the surface roughness was substantially the same as that of the initial.

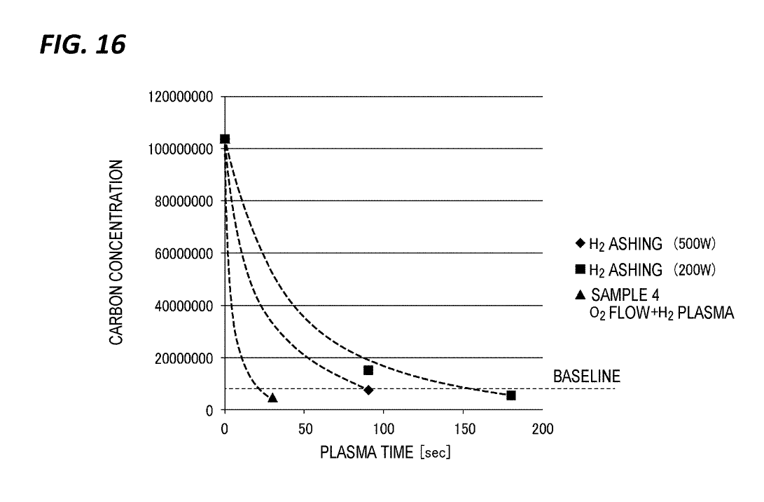

Further, a change in residual carbon concentration with respect to plasma time was grasped with respect to sample 4, a case of H₂ ashing at 200 W, and a case of H₂ ashing at 500 W. The results are illustrated in FIG. 16. As illustrated in the figure, until the carbon residual amount becomes equal to or less than the tolerance baseline, in the case of H₂ ashing, it took 180 sec at RF power of 200 W, which is the same as that in the case of sample 4 of the present exemplary embodiment, and it took 90 sec even at 500 W. However, in sample 4 of the present exemplary embodiment, the residual carbon amount become equal to or less than the baseline at the plasma time of 30 seconds.

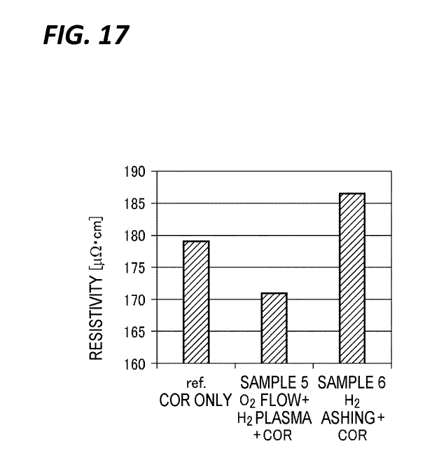

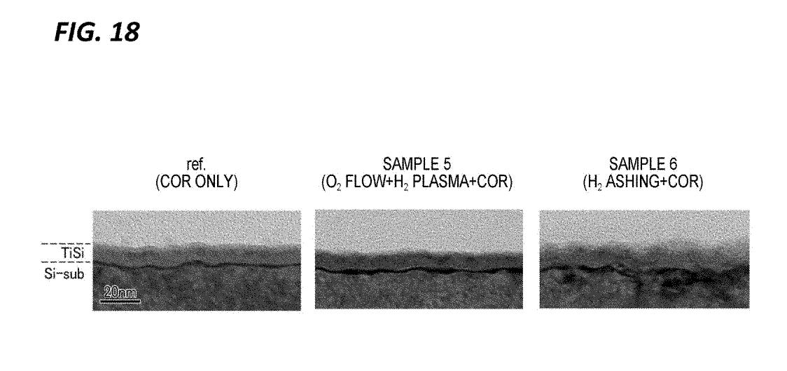

Next, the natural oxide film on the Si substrate (bare silicon wafer) was removed, and then a Ti film was formed by plasma CVD to form a TiSi contact. The film thickness of the Ti film was 5 nm. The natural oxide film removal was performed in three manners, that is, only by performing the COR processing with NH₃ gas and HF gas (31.5° C., etching amount: 4.5 nm) (reference), by performing the O₂ flow+H₂ plasma processing according to the present exemplary embodiment under the same conditions as in sample 4 and then performing the COR processing (31.5° C., etching amount: 1.5 nm) (sample 5), and by performing H₂ ashing (0.1 Torr, 500 W×90 sec) after etching with C₄F₈ (etching amount: 4.5 nm) and then performing the COR processing (31.5° C., etching amount: 1.5 nm) (sample 6). The resistivity of these contacts was measured. The results are illustrated in FIG. 17. In addition, sectional SEM photographs at this time are illustrated in FIG. 18. As illustrated in these figures, the resistivity of the sample 5 of the present exemplary embodiment was lower than that of the reference (ref.). In addition, the surface roughness was also satisfactory. Meanwhile, sample 6, on which H₂ ashing was performed, had poor surface roughness and had higher resistivity than that of the reference (ref.).

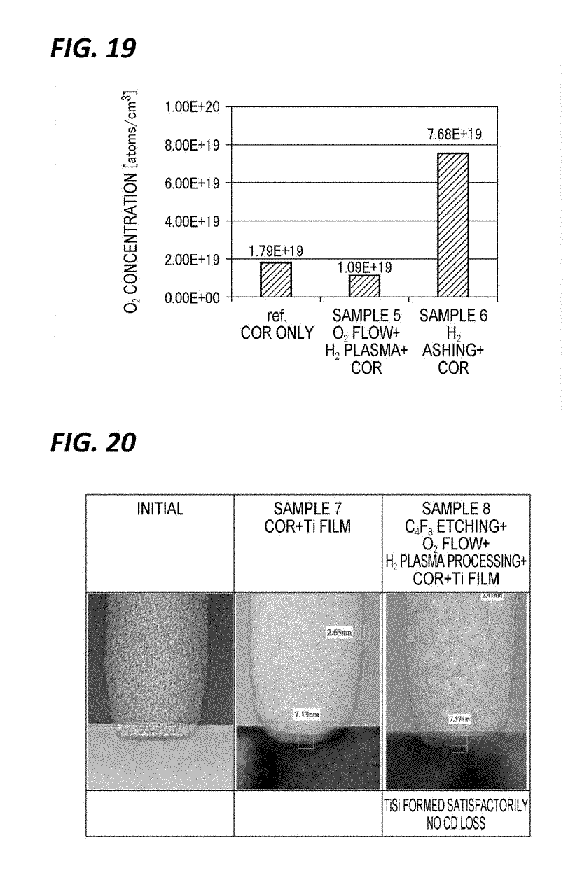

Next, for these, the oxygen concentration in the vicinity of the interface between the Ti film and the Si substrate was measured by SIMS measurement. The results are illustrated in FIG. 19. As illustrated in the figure, the oxygen concentration of the sample 5 of the present exemplary embodiment was lower than that of the reference (ref.). Meanwhile, sample 6, on which H₂ ashing was performed, exhibited an increase in the oxygen concentration on the contrary.

Next, comparison was made between a case where a natural oxide film on the bottom of the trench formed in the insulating film on the Si substrate was removed by COR only and then a Ti film was formed to form a TiSi contact (sample 7) and a case where C₄F₈ etching-O₂ flow-H₂ plasma processing was performed according to the present exemplary embodiment and then a Ti film was formed to form a TiSi contact (sample 8). FIG. 20 illustrates SEM photographs of cross-sections of a sample prior to the processing (initial), sample 7, and sample 8. As illustrated in FIG. 20, it was found that TiSi was formed satisfactorily in sample 8 and the CD loss was also small.

### Third Exemplary Embodiment

Next, an oxide film removing method according to a third exemplary embodiment will be described.

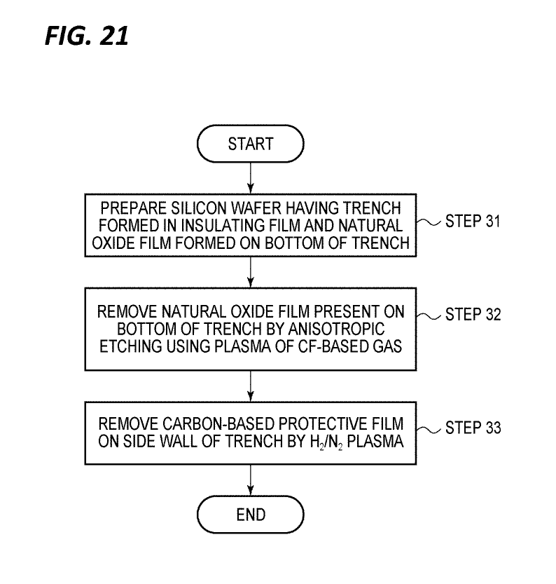

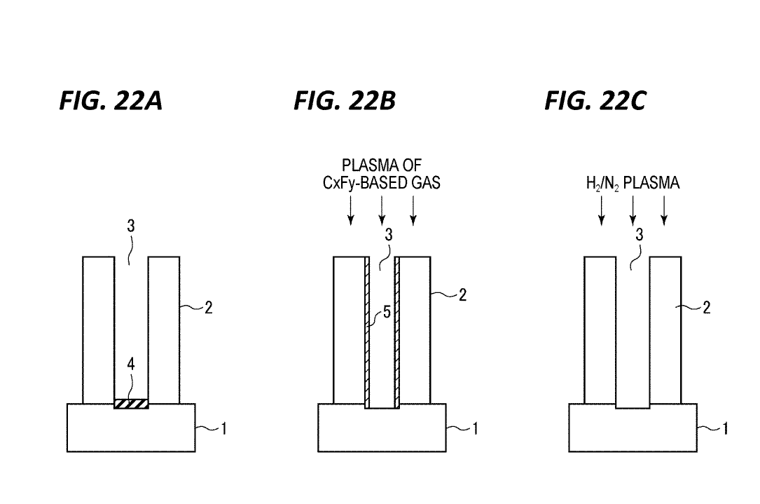

FIG. 21 is a flowchart illustrating an oxide film removing method according to a third exemplary embodiment. FIGS. 22A to 22C are sectional views illustrating the oxide film removing method step by step.

Also in the exemplary embodiment, descriptions will be made on a case of removing a natural oxide film formed on the surface of a silicon portion of the bottom of a trench formed as a predetermined pattern in a workpiece before forming a contact by depositing a contact metal on the silicon portion.

First, a processing target substrate (silicon wafer) having an insulating film 2 formed on a silicon base 1 and a trench 3 formed as a predetermined pattern in the insulating film 2 is prepared (step 31; FIG. 22A). A natural oxide film (silicon-containing oxide film) 4 is formed on the silicon portion on the bottom of the trench 3. The insulating film 2 is mainly made of a SiO₂ film. A part of the film may be a SiN film.

Prior to the oxide film removing processing, a cleaning processing (e.g., a pre-clean processing) may be performed on a workpiece (silicon wafer).

Next, the natural oxide film 4 on the bottom of the trench is removed by ionic anisotropic etching with plasma of a carbon-containing gas (step 32; FIG. 22B).

As in step 2 in the first exemplary embodiment, a fluorocarbon-based (CₓF_{y}-based) gas (e.g., CF₄ or C₄F₈) may be suitably used as the carbon-containing gas. Further, a fluorinated hydrocarbon-based (CₓH_{y}F_{z}-based) gas (e.g., CH₂F₂) may also be used. Further, in addition to these, a rare gas (e.g., Ar gas), an inert gas (e.g., N₂ gas), and even a slight amount of O₂ gas may be contained. Therefore, a carbon-based protective film is formed on the side walls of the trench 3. Thus, it is possible to etch the natural oxide film while suppressing the etching progress of the side walls. The pressure at the time of performing the anisotropic etching in step 32 is set to about 0.1 Torr (13.3 Pa) or less as in step 2 of the first exemplary embodiment.

Next, the carbon-based protective film on the side walls of the trench is removed (step 33). As described above, as described in Japanese Patent Laid-Open Publication No. 2003-059911, when ashing with oxygen gas or a gas containing oxygen as a main component is used to remove the carbon-based protective film, there is a possibility of re-oxidation of the base silicon, and when H₂ ashing is used, the removal processing with power that does not damage the base will take a long time. Further, when the power is increased to perform the removal in a short time, the base will be damaged.

Accordingly, in the present exemplary embodiment, H₂/N₂ plasma processing is used as step 33 for removing the carbon-based protective film (FIG. 22C). Therefore, the carbon-based protective film may be removed in a short time without damaging the base.

The H₂/N₂ plasma is obtained by converting a gas obtained by adding N₂ gas to H₂ gas into plasma, but the carbon removal action may be increased by adding N₂ gas. Thus, it is possible to remove the carbon-based protective film in a short time without damaging the base and with low power without oxidizing the base.

The conditions for the H₂/N₂ plasma processing step in step 33 are as follows: pressure: 0.02 Torr to 0.5 Torr (2.67 Pa to 66.7 Pa), H₂ gas flow rate: 10 sccm to 5,000 sccm, N₂ gas flow rate: 5 sccm to 5,000 sccm, RF power: 10 W to 1,000 W, and time: 0.1 sec to 120 sec. The pressure may be 0.05 Torr to 0.5 Torr (6.67 Pa to 66.7 Pa), the H₂ gas flow rate may be 100 sccm to 1,000 sccm, the N₂ gas flow rate may be 10 sccm to 1,000 sccm, the RF power may be 100 W to 500 W, and the time may be 10 sec to 90 sec.

When the natural oxide film is removed up to step 33, the process is terminated at step 33. In the case where the bottom of the trench 3 has a complicated shape like the processing target substrate for forming the fin FET, after step 33 is completed, isotropic etching by chemical etching (step 3 of the first exemplary embodiment) and residue removal, for example, removal of AFS which is a reaction product (step 4 of first exemplary embodiment) are performed as in the first exemplary embodiment.

Then, after the natural oxide film is removed as described above, a contact made of silicate may be formed by steps 12 to 13 illustrated in FIGS. 7 and 8A to 8C.

Also in the case of the present exemplary embodiment, a series of processings may be performed in the same chamber by using an oxide film removing apparatus illustrated in FIG. 9. Furthermore, when such an oxide film removing apparatus is installed in the multi-chamber type contact forming system illustrated in FIG. 10, a contact made of silicate may be formed with high throughput while suppressing oxidation.

[Test Result in Third Exemplary Embodiment]

Next, test results in the third exemplary embodiment will be described.

First, a residual carbon concentration and a residual oxygen concentration were measured by XPS in a case where etching with C₄F₈ gas was performed on a Si substrate (bare silicon wafer) (sample 1 in the second exemplary embodiment), a case where an O₂ flow+H₂ plasma processing was performed on a Si substrate (bare silicon wafer) after etching with C₄F₈ gas (sample 4), and a case where a H₂/N₂ plasma processing was performed on a Si substrate (bare silicon wafer) after etching with C₄F₈ gas (sample 11).

The conditions of sample 11 are as follows.

Pressure: 0.1 Torr

H₂ gas flow rate: 485 sccm

N₂ gas flow rate: 50 sccm

RF power: 100 W

Time: 60 sec

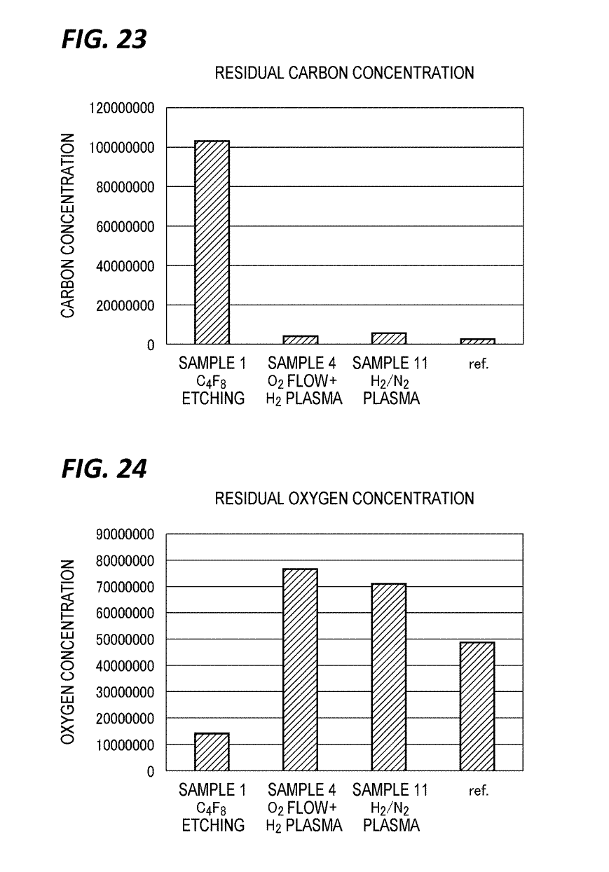

FIG. 23 illustrates the residual carbon concentrations of these samples, and FIG. 24 illustrates the residual oxygen concentrations of these samples. The reference (ref.) represents a value of the silicon substrate (bare silicon).

As illustrated in these figures, it has been found that sample 11, on which the H₂/N₂ plasma processing according to the present exemplary embodiment was performed, had the same residual oxygen concentration as that of sample 4 according to the second exemplary embodiment, and the residual carbon concentration also become lower. Further, sample 11 had the same surface roughness as that of the initial.

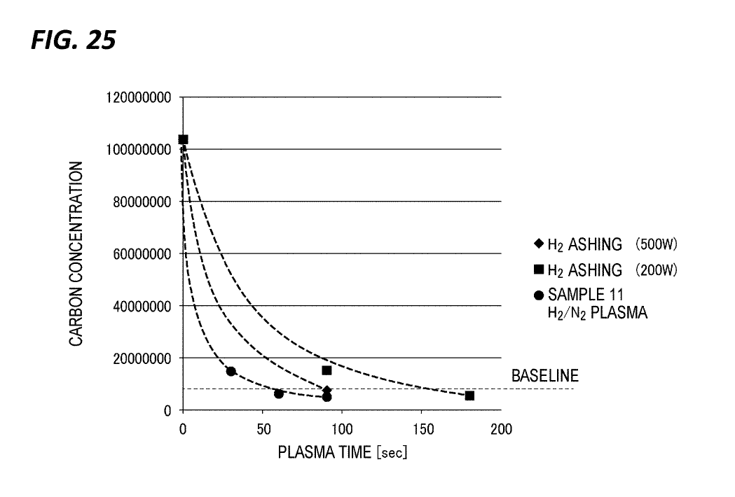

Further, a change in residual carbon concentration with respect to plasma time was grasped with respect to sample 11, a case of H₂ ashing at 200 W, and a case of H₂ ashing at 500 W. The results are illustrated in FIG. 25. As illustrated in the figure, in the case of H₂ ashing, it took 180 sec at RF power of 200 W until the carbon residual amount become equal to or less than the tolerance baseline, and it took 90 sec even at 500 W. However, in sample 11 of the present exemplary embodiment, the residual carbon amount become equal to or less than the baseline at the plasma time of 60 seconds even though the RF power was 100 W.

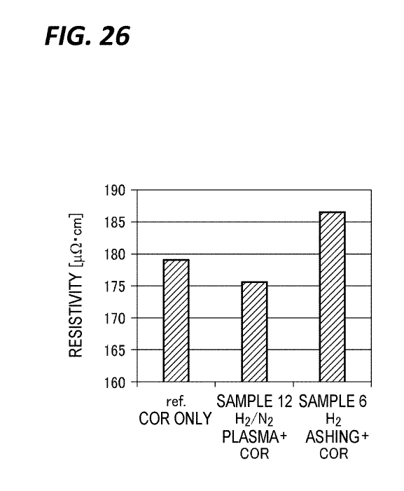

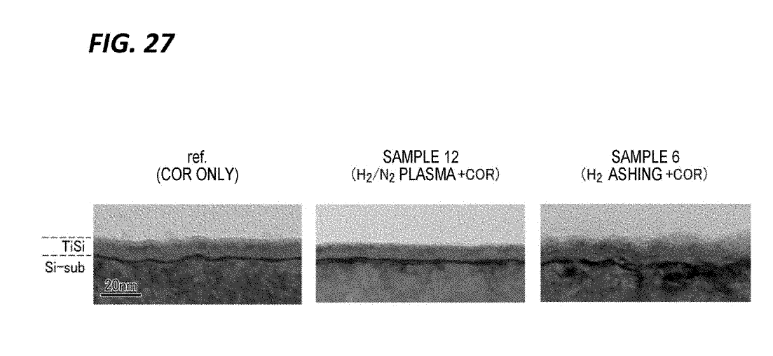

Next, the natural oxide film on the Si substrate (bare silicon wafer) was removed, and then a Ti film was formed by plasma CVD to form a TiSi contact. The film thickness of the Ti film was 5 nm. The natural oxide film removal was performed in three manners, that is, only by the COR processing with NH₃ gas and HF gas (31.5° C., etching amount: 4.5 nm) (reference), by performing the H₂/N₂ plasma processing according to the present exemplary embodiment under the same conditions as in sample 11 and then performing the COR processing (31.5° C., etching amount: 1.5 nm) (sample 12), and by, performing H₂ ashing (0.1 Torr, 500 W×90 sec) after etching with C₄F₈ (etching amount 4.5 nm) and then performing the COR processing (31.5° C., etching amount: 1.5 nm) (sample 6 in the second exemplary embodiment). The resistivity of these contacts was measured. The results are illustrated in FIG. 26. In addition, sectional SEM photographs at this time are illustrated in FIG. 27. As illustrated in these figures, the resistivity of the sample 12 of the present exemplary embodiment was lower than that of the reference (ref.). In addition, the surface roughness was also satisfactory. Meanwhile, sample 6, on which H₂ ashing as described above, had poor surface roughness and had higher resistivity than that of the reference (ref.).

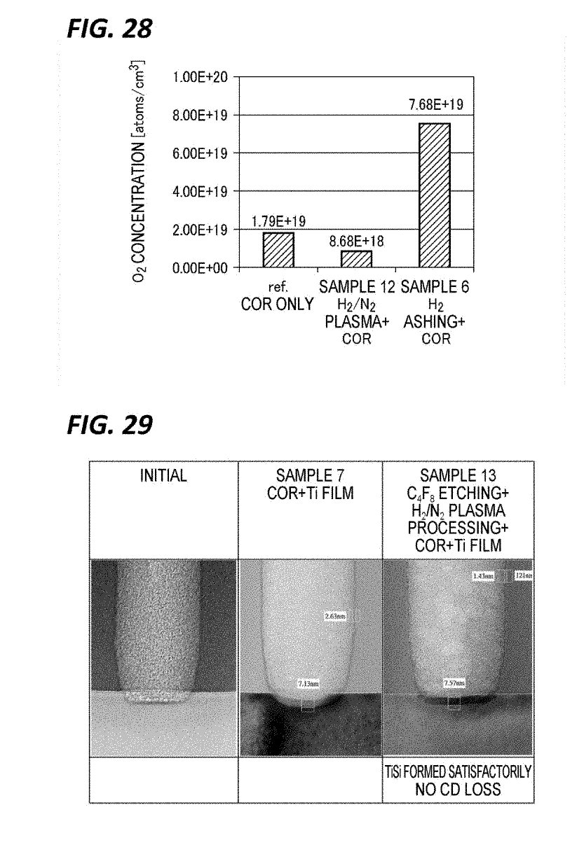

Next, for these, the oxygen concentration in the vicinity of the interface between the Ti film and the Si substrate was measured by SIMS measurement. The results are illustrated in FIG. 28. As illustrated in the figure, the oxygen concentration of the sample 12 of the present exemplary embodiment was lower than that of the reference (ref.). Meanwhile, sample 6, on which H₂ ashing was performed, exhibited an increase in the oxygen concentration on the contrary.

Next, comparison was made between a case where a natural oxide film on the bottom of the trench formed in the insulating film on the Si substrate was removed by COR only and then a Ti film was formed to form a TiSi contact (sample 7 in the second exemplary embodiment) and a case where C₄F₈ etching-H₂/N₂ plasma processing was performed and the COR was further performed according to the present exemplary embodiment and then a Ti film was formed to form a TiSi contact (sample 13). FIG. 29 illustrates SEM photographs of cross-sections of a sample prior to the processing (initial), sample 7, and sample 13. As illustrated in FIG. 29, it was found that TiSi was formed satisfactorily in sample 13 and the CD loss was also small.

### Fourth Exemplary Embodiment

Next, an oxide film removing method according to a fourth exemplary embodiment will be described.

Also in the exemplary embodiment, descriptions will be made on a case of removing a natural oxide film formed on the surface of a silicon portion of the bottom of a trench formed as a predetermined pattern in a workpiece before forming a contact by depositing a contact metal on the silicon portion.

In the second exemplary embodiment and the third exemplary embodiment, the natural oxide film on the bottom of the trench is removed by ionic anisotropic etching with plasma of a carbon-containing gas (e.g., CₓF_{y}), and then the carbon-based protective film present on the side walls of the trench is removed by O₂ flow+H₂ plasma (the second exemplary embodiment) or H₂/N₂ plasma (the third exemplary embodiment) while suppressing the re-oxidation of the base silicon or the damage to the base.

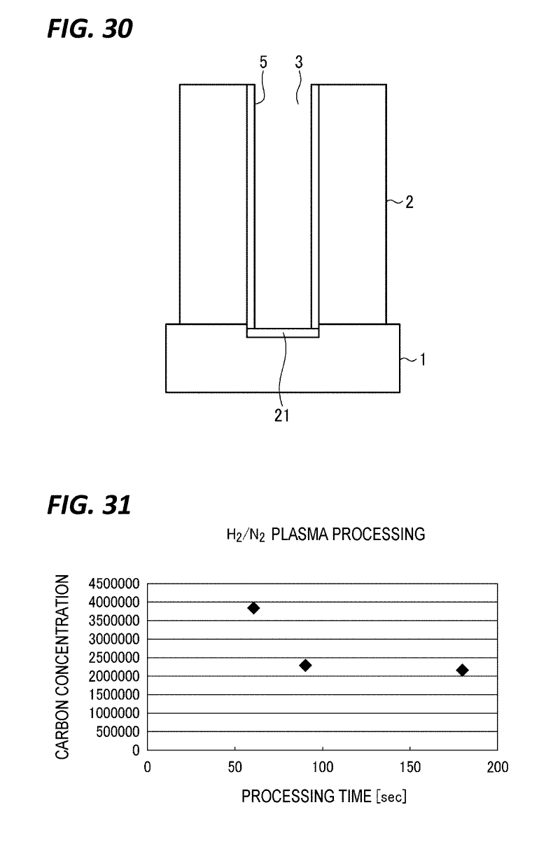

However, when the ionic anisotropic etching is performed with plasma of a carbon-containing gas (e.g., CₓF_{y}), for example, carbon or fluorine is implanted into the surface of the base silicon substrate 1 as illustrated in FIG. 30 to form a very thin carbon-containing layer 21 slightly containing these impurities, which may cause problems such as, for example, an increase in contact resistance. In the O₂ flow+H₂ plasma and H₂/N₂ plasma, the carbon-based protective film is removed, but the carbon-containing layer 21 on the surface of the base silicon substrate 1 may not be removed. FIG. 31 illustrates this problem, and illustrates the relationship between the processing time of the H₂/N₂ plasma processing and the carbon amount. As illustrated in the figure, it is found that the amount of the carbon is decreased initially, but after a certain period of time, the amount of the carbon is hardly decreased and the carbon implanted into the surface of the silicon substrate 1 is unable to be removed.

Further, even when the remaining portion of the natural oxide film on the bottom of the trench is removed by performing the COR processing thereafter, it is difficult to remove the carbon-containing layer 21 because the COR processing is a processing of removing the oxide film.

In order to remove such impurities, a technique of releasing the silicon wafer to the atmosphere to sacrifice the silicon wafer by oxidation and removing the oxide film and contaminants by wet cleaning has been used in the related art. However, in the contact metal processing, contamination may occur at the time of opening to the atmosphere. Thus, it is not realistic.

Therefore, in the present exemplary embodiment, descriptions will be made on an oxide film removing method capable of removing also the carbon-containing layer 21 on the surface of the base silicon substrate 1.

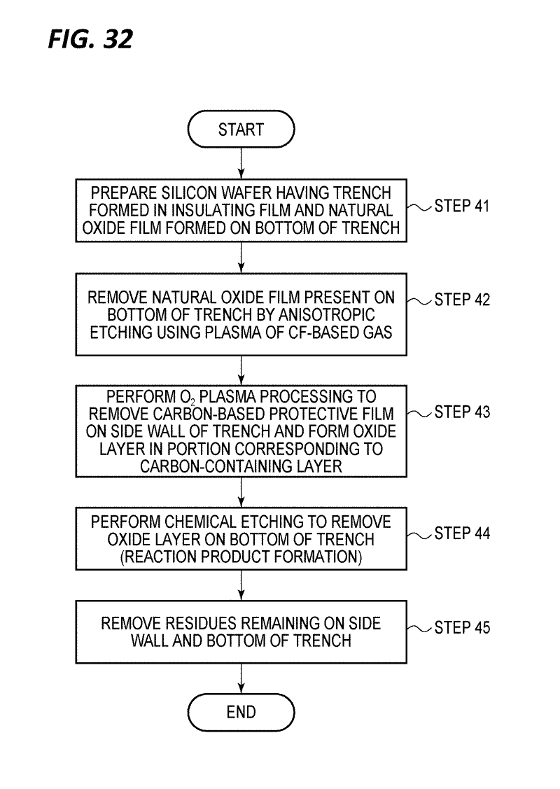

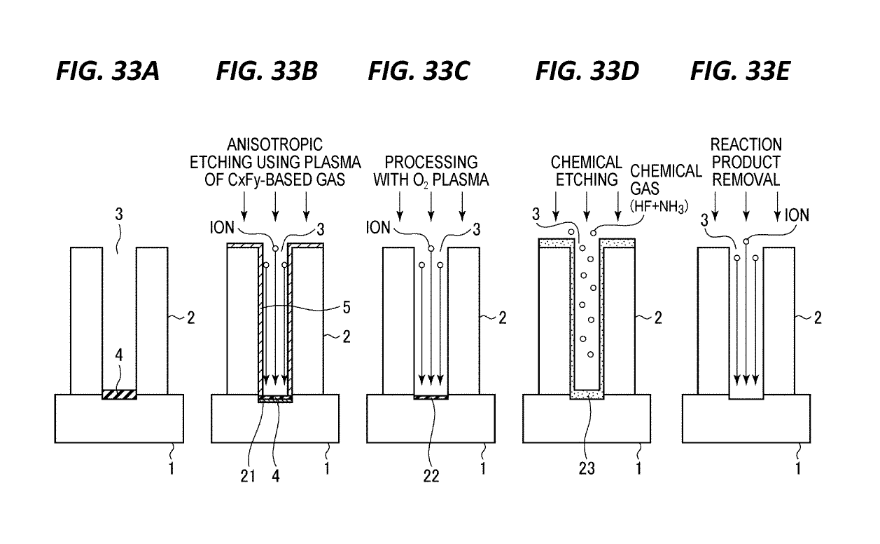

FIG. 32 is a flowchart illustrating an oxide film removing method according to the fourth exemplary embodiment. FIGS. 33A to 33E are sectional views illustrating the oxide film removing method step by step.

First, a processing target substrate (silicon wafer) having an insulating film 2 formed on a silicon base 1 and a trench 3 formed as a predetermined pattern in the insulating film 2 is prepared (step 41; FIG. 33A). A natural oxide film (silicon-containing oxide film) 4 is formed on the silicon portion on the bottom of the trench 3. The insulating film 2 is mainly made of a SiO₂ film. A part of the film may be a SiN film.

Prior to the oxide film removing processing, a cleaning processing (e.g., a pre-clean processing) may be performed on a workpiece (silicon wafer).

Next, the natural oxide film 4 on the bottom of the trench is removed by ionic anisotropic etching with plasma of a carbon-containing gas (step 42; FIG. 33B).

The ionic anisotropic etching at this time is performed in the same manner as in the first to third exemplary embodiments. Therefore, a carbon-based protective film 5 is formed on the side walls of the trench 3. Thus, it is possible to etch the natural oxide film while suppressing the etching progress of the side walls. Meanwhile, at this time, for example, CₓF_{y} is implanted into the surface of the silicon substrate 1 to form the carbon-containing layer 21 as described above.

Next, an O₂ plasma processing is performed (step 43; FIG. 33C). By the 02 plasma processing, the carbon-based protective film on the side walls of the trench is removed and at the same time, a portion corresponding to the carbon-containing layer 21 on the surface of the silicon substrate 1 is oxidized extremely thinly to form a very thin oxide film 4 which is in a state of incorporating, for example, carbon contained in the carbon-containing layer 21 and is integrated with the rest of the natural oxide film 4.

The conditions for the O₂ plasma processing in step 43 are as follows: O₂ gas flow rate: 10 sccm to 5,000 sccm, pressure: 0.1 Torr to 2.0 Torr (13.3 Pa to 266.6 Pa), RF power: 100 W to 500 W, processing time: 10 sec to 120 sec.

Next, chemical etching is performed (step 44; FIG. 33D). Therefore, the chemical gas reacts with the oxide film 22 present in the bottom portion of the trench 3, which are in turn removed. At this time, a reaction product 23 containing, for example, carbon is generated on the bottom of the trench 3 by the reaction between the oxide film 22 generated in step 43 and the chemical gas. Since the chemical etching is isotropic etching, the oxide in the complicated shape portion on the bottom of the trench may also be removed. The reaction product 23 is also generated on the upper surface of the insulating film 2 and the side walls of the trench 3.

Similarly to the first exemplary embodiment, the COR processing using NH₃ gas and HF gas may be suitably used for the chemical processing. An inert gas (e.g., Ar gas or N₂ gas) may be added as a diluent gas. The conditions at this time are the same as those in the first exemplary embodiment. The reaction product 23 mainly contains ammonium fluorosilicate ((NH₄)₂SiF₆; AFS).

Next, the reaction product 23 remaining on the side walls and the bottom of the trench 3 is removed (step 45; FIG. 33E).

The reaction product removal processing in step 45 may be performed by, for example, H₂ plasma which is plasma of a H₂-containing gas. As a result, it is possible to remove the reaction product 23 while suppressing re-oxidation of the side walls and the bottom portion. The conditions at this time may be set to be substantially the same as in step 4 of the first exemplary embodiment.

As described above, in the present exemplary embodiment, the carbon-containing layer 21 formed on the surface of the silicon substrate 1 is oxidized by the O₂ plasma to form the oxidized layer 22, and impurities (e.g., carbon) are removed along with the oxide layer 22 by chemical etching such as the COR processing (and reaction product removal). Therefore, the reactivity between Ti and the substrate Si may be improved in the bottom portion of the trench, and the contact resistance may be reduced. Further, since the O₂ plasma has a high carbon removal ability, the processing time of the carbon-containing protective film removal processing may be shortened as compared with the second exemplary embodiment and the third exemplary embodiment. Furthermore, since the removal ability of the CF-based film formed on the inner wall of the chamber is also high, it is possible to reduce the particles caused by peeling off of the CF-based film.

Further, the chemical processing (e.g., O₂ plasma processing and COR processing) may be performed in a vacuum. Thus, unlike the sacrificial oxidation in the related art, since the oxide layer 22 is removed without exposing to the atmosphere, it is possible to solve the problem of contamination at the time of opening to the atmosphere.

In the second exemplary embodiment and the third exemplary embodiment described above, it is directed to lower the residual carbon concentration as well as the residual oxygen concentration, but in the present exemplary embodiment, since the oxide film removal processing (e.g., the COR processing) is performed thereafter, the residual oxygen concentration does not become a problem.

[Test Result in Fourth Exemplary Embodiment]

Next, test results in the fourth exemplary embodiment will be described.

First, a residual carbon concentration was measured by XPS in a case where only the COR processing was performed on a Si substrate (bare silicon wafer) (sample 21), a case where a H₂/N₂ plasma processing was performed on a Si substrate (bare silicon wafer) after etching with C₄F₈ gas (sample 22), and a case where O₂ ashing was performed on a Si substrate (bare silicon wafer) after etching with C₄F₈ gas (sample 23). The processing conditions of sample 22 were the same as those of sample 11 of the third exemplary embodiment, except that the time was 180 sec. The processing conditions of sample 23 were the same as the processing conditions of sample 2 of the second exemplary embodiment, and the processing of sample 23 was performed for 120 sec.

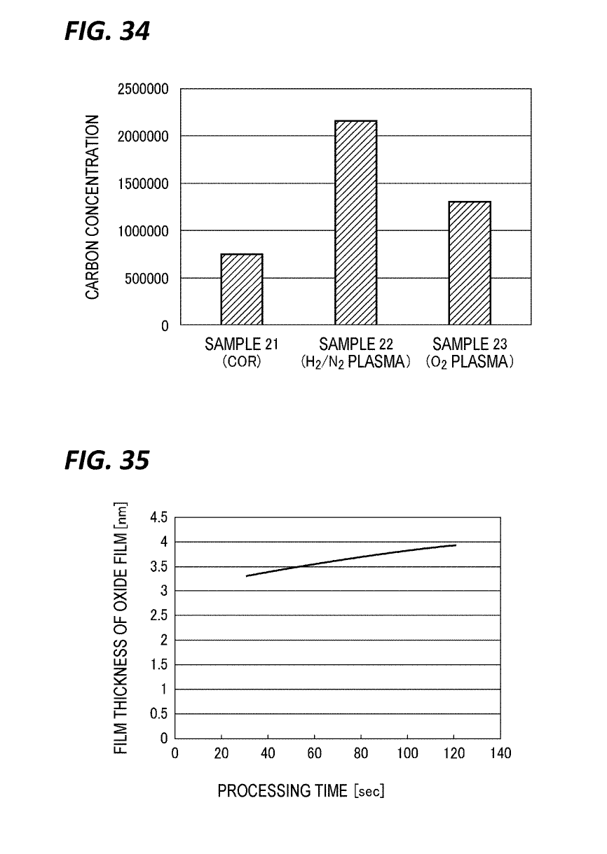

The results thereof are illustrated in FIG. 34. As illustrated in the figure, it can be seen that sample 23, on which the O₂ plasma processing was performed after etching with C₄F₈ gas, had a residual carbon concentration higher than that of sample 21, on which the etching with C₄F₈ gas was performed, but lower than sample 22, on which the H₂/N₂ plasma processing was performed.

Next, a test was performed on the relationship between the processing time in O₂ plasma processing after etching with C₄F₈ gas and the oxide film thickness. FIG. 35 is a view illustrating the results. As illustrated in this figure, the growth rate of the oxide film was about 0.5 nm/min, and it was found that the controllability was sufficient.

### Fifth Exemplary Embodiment

Next, an oxide film removing method according to a fifth exemplary embodiment will be described.

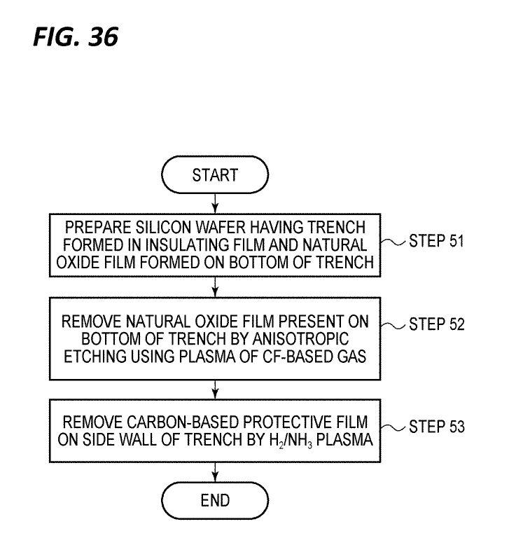

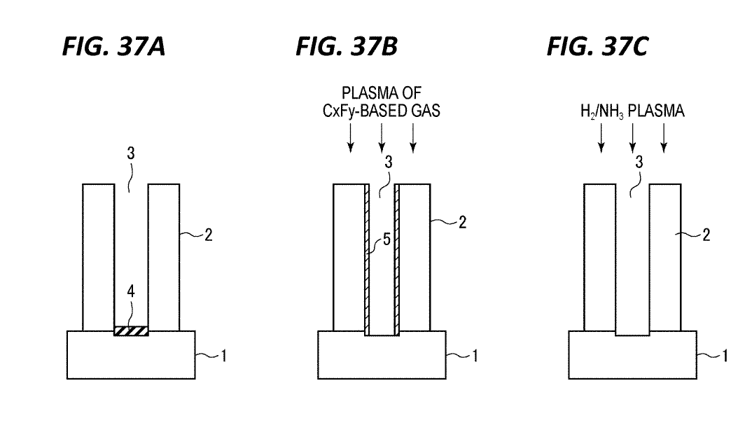

FIG. 36 is a flowchart illustrating an oxide film removing method according to the fifth exemplary embodiment. FIGS. 37A to 37C are sectional views illustrating the oxide film removing method step by step.

Also in the exemplary embodiment, descriptions will be made on a case of removing a natural oxide film formed on the surface of a silicon portion of the bottom of a trench formed as a predetermined pattern in a workpiece before forming a contact by depositing a contact metal on the silicon portion.

First, a processing target substrate (silicon wafer) having an insulating film 2 formed on a silicon base 1 and a trench 3 formed as a predetermined pattern in the insulating film 2 is prepared (step 51; FIG. 37A). A natural oxide film (silicon-containing oxide film) 4 is formed on the silicon portion on the bottom of the trench 3. The insulating film 2 is mainly made of a SiO₂ film. A part of the film may be a SiN film.

Prior to the oxide film removing processing, a cleaning processing (e.g., a pre-clean processing) may be performed on a workpiece (silicon wafer).

Next, the natural oxide film 4 on the bottom of the trench is removed by ionic anisotropic etching with plasma of a carbon-containing gas (step 52; FIG. 37B).

As in step 2 in the first exemplary embodiment, a fluorocarbon-based (CₓF_{y}-based) gas (e.g., CF₄ or C₄F₈) may be suitably used as the carbon-containing gas. Further, a fluorinated hydrocarbon-based (CₓH_{y}F_{z}-based) gas (e.g., CH₂F₂) may also be used. Further, in addition to these, a rare gas (e.g., Ar gas), an inert gas (e.g., N₂ gas), and even a slight amount of O₂ gas may be contained. Therefore, a carbon-based protective film is formed on the side walls of the trench 3. Thus, it is possible to etch the natural oxide film while suppressing the etching progress of the side walls. The pressure at the time of performing the anisotropic etching in step 32 is set to about 0.1 Torr (13.3 Pa) or less as in step 2 of the first exemplary embodiment.

Next, the carbon-based protective film on the side walls of the trench is removed (step 53). As described above, as described in Japanese Patent Laid-Open Publication No. 2003-059911, when ashing with oxygen gas or a gas containing oxygen as a main component is used to remove the carbon-based protective film, there is a possibility of re-oxidation of the base silicon, and when H₂ ashing is used, the removal processing with power that does not damage the base will take a long time. Further, when the power is increased to perform the removal in a short time, the base will be damaged.

In order to solve such a problem, in the third embodiment, H₂/N₂ plasma is used as a step of removing the carbon-based protective film. However, it is desired that the ashing rate be faster than the H₂/N₂ plasma and the concentrations of residual carbon and residual fluorine be further reduced.

Accordingly, in the present exemplary embodiment, H₂/NH₃ plasma processing is used as step 53 for removing the carbon-based protective film (FIG. 37C). Therefore, the carbon-based protective film may be removed in a short time without damaging the base, and the concentrations of residual carbon and residual fluorine after removal of the carbon-based protective film may be reduced.

The H₂/NH₃ plasma is obtained by converting a gas obtained by adding NH₃ gas to H₂ gas into plasma. However, adding NH₃ gas makes it possible to expect high concentration of N—H bonds, and it is possible to suppress the concentrations of residual fluorine and residual carbon while increasing the carbon removing action Therefore, the carbon-based protective film may be removed in a short time in a state where the residual fluorine and the residual carbon are reduced without oxidizing the substrate and damaging the substrate with low power.

The conditions for the H₂/NH₃ plasma processing step in step 53 are as follows: the pressure: 0.1 Torr to 1.0 Torr (13.3 Pa to 133.3 Pa), the H₂ gas flow rate: 10 sccm to 5,000 sccm, the NH₃ gas flow rate: 1 sccm to 1,000 sccm, the RF power: 10 W to 1,000 W, and the time: 1 sec to 150 sec. The pressure may be 0.3 Torr to 0.7 Torr (40.0 Pa to 93.3 Pa), the H₂ gas flow rate may be 100 sccm to 700 sccm, the NH₃ gas flow rate may be 5 sccm to 500 sccm, the RF power may be 50 W to 500 W, and the time may be 10 sec to 120 sec. In addition, the flow rate ratio of NH₃ gas to H₂ gas+NH₃ gas may be 50% or less, and preferably 0.1% to 25%.

When the natural oxide film is removed up to step 53, the process is terminated at step 53. Further, in the case where the bottom of the trench 3 has a complicated shape like the processing target substrate for forming the fin FET, after step 53 is completed, isotropic etching by chemical etching (step 3 of the first exemplary embodiment) and residue removal, for example, removal of AFS which is a reaction product (step 4 of first exemplary embodiment) are performed as in the first exemplary embodiment.

Then, after the natural oxide film is removed as described above, a contact made of silicate may be formed by steps 12 to 13 illustrated in FIGS. 7 and 8A to 8C.

Also in the case of the present exemplary embodiment, a series of processings may be performed in the same chamber by using an oxide film removing apparatus illustrated in FIG. 9. Furthermore, when such an oxide film removing apparatus is installed in the multi-chamber type contact forming system illustrated in FIG. 10, a contact made of silicate may be formed with high throughput while suppressing oxidation.

[Test Result in Fifth Exemplary Embodiment]

Next, test results in the fifth exemplary embodiment will be described.

Here, the residual carbon concentration and the residual fluorine concentration were measured by XPA and compared with each other with respect to a case where a H₂/NH₃ plasma processing was performed on a Si substrate (bare silicon wafer) after etching with C₄F₈ gas (sample 31 in the third exemplary embodiment), a case where the flow rate ratio of NH₃ gas in the H₂/NH₃ plasma processing was set to be high after etching with C₄F₈ gas (sample 32: “high” NH₃ flow rate ratio), a case where the flow rate ratio of NH₃ gas in the H₂/NH₃ plasma processing was set to be lower than that of sample 32 after etching with C₄F₈ gas (sample 33: “medium” NH₃ flow rate ratio), and a case where the flow rate ratio of NH₃ gas in the H₂/NH₃ plasma processing was set to be further lower after etching with C₄F₈ gas (sample 34: “low” NH₃ flow rate ratio).

The conditions of the present test are as follows.
Sample 31 (Third Exemplary Embodiment)
Pressure: 0.5 Torr, H₂ gas flow rate: 400 sccm, N₂ gas flow rate: 50 sccm, RF power: 200 W, and Time: 180 sec
Sample 32 (“High” NH₃ flow rate ratio)
Pressure: 0.5 Torr, H₂ gas flow rate: 350 sccm, NH₃ gas flow rate: 100 sccm, RF power: 200 W, and Time: 180 sec
Sample 33 (“Medium” NH₃ flow rate ratio)
Pressure: 0.5 Torr, H₂ gas flow rate: 400 sccm, NH₃ gas flow rate: 50 sccm, RF power: 200 W, and Time: 180 sec
Sample 34 (“Low” NH₃ flow rate ratio)
Pressure: 0.5 Torr, H₂ gas flow rate: 430 sccm, NH₃ gas flow rate: 20 sccm, RF power: 200 W, and Time: 180 sec

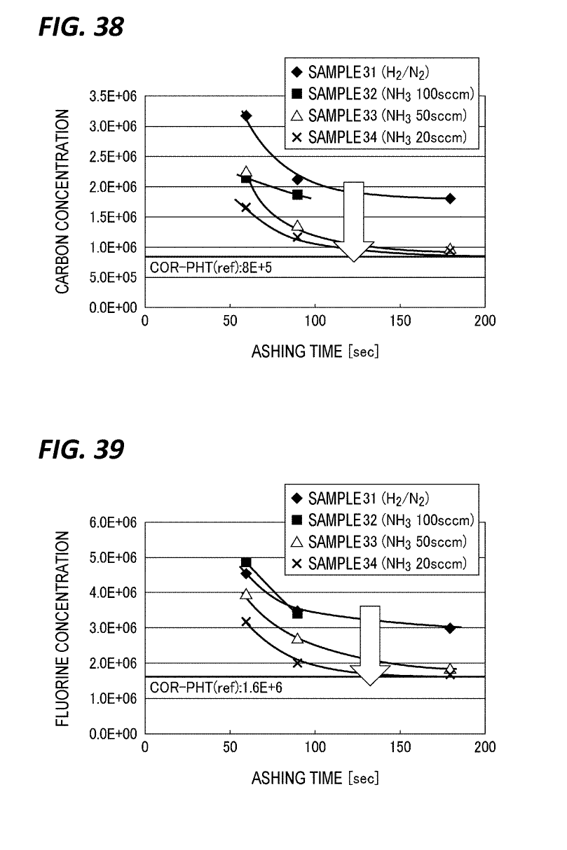

FIG. 38 illustrates the residual carbon concentrations of these samples, and FIG. 39 illustrates the residual fluorine concentrations of these samples.

As illustrated in figures, it has been found that the residual carbon concentration and the residual fluorine concentration may be reduced by adding NH₃ gas to H₂ gas, and the effect of reducing the residual carbon concentration and the residual carbon concentration is increased as the flow rate of the NH₃ gas becomes lower in a range of 20 sccm to 100 sccm (the NH₃ gas flow rate ratio is in a range of 4.4% to 22.2%).

<Other Applications>

Although the exemplary embodiment of the present disclosure has been described above, the present disclosure is not limited to the above-described exemplary embodiment and may be variously modified.

For example, in the above exemplary embodiment, descriptions have been made on the case where the present disclosure is used for removing the natural oxide film in the contact portion of the bottom of the trench of the fin FET. However, the present disclosure is not limited thereto and may be applied to removal of the oxide film formed at the bottom of the fine pattern. Although the trench is exemplified as a pattern, the pattern is not limited to the trench, but may be another form such as, for example, a via hole.

Further, in the first exemplary embodiment, descriptions have been made on an example in which removal of residues after chemical etching and removal of the carbon-based protective film remaining after removing the oxide film are performed using H₂, but the present disclosure is not limited thereto.

Further, in the above exemplary embodiment, a silicon wafer is used as the target substrate, but, the present disclosure is not limited thereto. Any substrate such as, for example, a compound semiconductor, a glass substrate, or a ceramic substrate may be used as long as the silicon-containing oxide film is present on the bottom of the trench.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method for removing, from a processing target substrate having an insulating film with a predetermined pattern formed thereon, a silicon-containing oxide film formed in a silicon portion of a bottom of the pattern, the method comprising:
removing the silicon-containing oxide film formed on the bottom of the pattern by ionic anisotropic plasma etching using plasma of a carbon-based gas;
removing a remaining portion of the silicon-containing oxide film after the anisotropic plasma etching, by chemical etching; and
removing a residue remaining after the chemical etching.

2. The method of claim 1, wherein the silicon-containing oxide film on the bottom of the pattern is a natural oxide film formed on a surface of the silicon portion of the bottom of the pattern.

3. The method of claim 2, wherein the processing target substrate is a substrate for forming a fin FET and has a silicon fin and an epitaxial growth portion made of Si or SiGe formed at a tip portion of the silicon fin, and the epitaxial growth portion constitutes the silicon portion.

4. The method of claim 1, wherein the removing the residue is performed by a H₂-containing plasma processing using plasma of a H₂-containing gas.

5. The method of claim 1, further comprising:
removing a carbon-based protective film remaining on a side wall of the pattern after the anisotropic plasma etching,
wherein the removing the residue is performed to remove a reaction product generated by the chemical etching.

6. The method of claim 5, wherein the removing the carbon-based protective film is performed by a H₂-containing plasma processing using plasma of a H₂-containing gas.

7. The method of claim 6, wherein the removing the carbon-based protective film is performed by the H₂-containing plasma processing after an O₂-containing gas is supplied to the processing target substrate.

8. The method of claim 6, wherein the removing the carbon-based protective film is performed by a H₂/N₂ plasma processing using plasma of H₂ gas and N₂ gas.

9. The method of claim 6, wherein the removing the carbon-based protective film is performed by a H₂/NH₃ plasma processing using plasma of H₂ gas and NH₃ gas.

10. The method of claim 5, wherein the removing the carbon-based protective film is performed by an O₂ gas plasma processing.

11. The method of claim 1, wherein the anisotropic plasma etching is performed by plasma of a fluorocarbon-based gas or a fluorinated hydrocarbon-based gas.

12. The method of claim 1, wherein the anisotropic plasma etching is performed at a pressure of 0.1 Torr or less.

13. The method of claim 1, wherein the chemical etching is performed by a gas processing using NH₃ gas and HF gas.

14. The method of claim 1, wherein the insulating film includes a SiO₂ film.

15. The method of claim 1, wherein the removing the silicon-containing oxide film, the removing a remaining portion, and the removing the residue are performed at the same temperature within a range of 10° C. to 150° C.

16. The method of claim 15, wherein the removing the silicon-containing oxide film, the removing a remaining portion, and the removing the residue are performed at substantially the same temperature within a range of 20° C. to 60° C.

17. The method of claim 1, wherein the removing the silicon-containing oxide film, the removing a remaining portion, and the removing the residue are performed continuously in a single processing container.

18. A method for removing, from a processing target substrate having an insulating film with a predetermined pattern formed thereon, a silicon-containing oxide film formed in a silicon portion of a bottom of the pattern, the method comprising:
removing the silicon-containing oxide film formed on the bottom of the pattern by ionic anisotropic plasma etching using plasma of a carbon-based gas; and
removing a carbon-based protective film remaining on a side wall of the pattern after the anisotropic plasma etching,
wherein the removing the carbon-based protective film is performed by a H₂-containing plasma processing is performed using plasma of a H₂-containing gas after an O₂-containing gas is supplied to the processing target substrate.

19. The method of claim 18, wherein the O₂-containing gas is supplied at a flow rate of 10 sccm to 5,000 sccm and a time of 0.1 sec to 120 sec.

20. The method of claim 19, wherein the O₂-containing gas is supplied at a flow rate of 100 sccm to 1,000 sccm and a time of 1 sec to 10 sec.

21. The method of claim 18, wherein the H₂-containing plasma processing is performed with a pressure of 0.02 Torr to 0.5 Torr, an H₂ gas flow rate of 10 sccm to 5,000 sccm, an RF power of 10 W to 1,000 W, and a time of 1 sec to 120 sec.

22. The method of claim 21, wherein the H₂-containing plasma processing is performed with a pressure of 0.05 Torr to 0.3 Torr, an H₂ gas flow rate of 100 sccm to 1,000 sccm, an RF power of 100 W to 500 W, and a time of 5 sec to 90 sec.

23. The method of claim 18, wherein in the removing the carbon based protective film, the supply of the O₂-containing gas to the processing target substrate and the H₂-containing plasma processing using the plasma of the H₂-containing gas are performed a plurality of times.

24. A method for removing, from a processing target substrate having an insulating film with a predetermined pattern formed thereon, a silicon-containing oxide film formed in a silicon portion of a bottom of the pattern, the method comprising:
removing the silicon-containing oxide film formed on the bottom of the pattern by ionic anisotropic plasma etching using plasma of a carbon-based gas; and
removing a carbon-based protective film remaining on a side wall of the pattern after the anisotropic plasma etching,
wherein the removing the carbon-based protective film is performed by a H₂/N₂ plasma processing using plasma of H₂ gas and N₂ gas.

25. The method of claim 24, wherein the H₂/N₂ plasma processing is performed with a pressure of 0.02 Torr to 0.5 Torr, an H₂ gas flow rate of 10 sccm to 5,000 sccm, an N₂ gas flow rate of 5 sccm to 5,000 sccm, an RF power of 10 W to 1,000 W, and a time of 1 sec to 120 sec.

26. The method of claim 25, wherein the H₂/N₂ plasma processing is performed with a pressure of 0.05 Torr to 0.3 Torr, an H₂ gas flow rate of 100 sccm to 1,000 sccm, an N₂ gas flow rate of 10 sccm to 1,000 sccm, an RF power of 100 W to 500 W, and a time of 10 sec to 90 sec.

27. A method for removing, from a processing target substrate having an insulating film with a predetermined pattern formed thereon, a silicon-containing oxide film formed in a silicon portion of a bottom of the pattern, the method comprising:
removing the silicon-containing oxide film formed on the bottom of the pattern by ionic anisotropic plasma etching using plasma of a carbon-based gas; and
removing a carbon-based protective film remaining on a side wall of the pattern after the anisotropic plasma etching,
wherein the removing the carbon-based protective film is performed by a H₂/NH₃ plasma processing using plasma of H₂ gas and NH₃ gas.

28. The method of claim 27, wherein the H₂/NH₃ plasma processing is performed with a pressure of 0.1 Torr to 1.0 Torr, an H₂ gas flow rate of 10 sccm to 5,000 sccm, an NH₃ gas flow rate of 1 sccm to 1,000 sccm, an RF power of 10 W to 1,000 W, and a time of 1 sec to 150 sec.

29. The method of claim 28, wherein the H₂/NH₃ plasma processing is performed with a pressure of 0.3 Torr to 0.7 Torr, an H₂ gas flow rate of 100 sccm to 700 sccm, an NH₃ gas flow rate of 5 sccm to 500 sccm, an RF power of 50 W to 500 W, and a time of 10 sec to 120 sec.

30. The method of claim 27, wherein a flow rate ratio of NH₃ gas to H₂ gas+NH₃ gas in the H₂/NH₃ plasma processing is in a range of 0.1% to 25%.

31. An apparatus for removing, from a processing target substrate having an insulating film with a predetermined pattern formed thereon, a silicon-containing oxide film formed in a silicon portion of a bottom of the pattern, the apparatus comprising:
a processing container that accommodates the processing target substrate;
a processing gas supply mechanism that supplies a predetermined processing gas into the processing container;
an exhaust mechanism that exhausts an atmosphere in the processing container;
a plasma generating mechanism that generates plasma in the processing container; and
a controller that controls the processing gas supply mechanism, the exhaust mechanism, and the plasma generating mechanism,
wherein the controller controls the processing gas supply mechanism, the exhaust mechanism, and the plasma generating mechanism to perform the method of claim 1.

32. A contact forming method comprising:
removing, from a processing target substrate having an insulating film with a predetermined pattern formed thereon, a silicon-containing oxide film formed in a silicon portion of a bottom of the pattern by the method of claim 1;
forming a metal film after the silicon-containing oxide film is removed; and
forming a contact on the bottom of the pattern by reacting the silicon portion with the metal film.

33. The contact forming method of claim 32, wherein the forming the metal film is performed by CVD or ALD.

34. A contact forming system that removes, from a processing target substrate having an insulating film with a predetermined pattern formed thereon, a silicon-containing oxide film formed in a silicon portion of a bottom of the pattern, and forms a contact in the silicon portion, the contact forming system comprising:
the apparatus of claim 31 that removes the silicon-containing film of the processing target substrate;
a metal film forming apparatus that forms a metal film after the silicon-containing oxide film is removed;
a vacuum conveyance chamber to which the oxide film removing apparatus and the metal film forming apparatus are connected; and
a conveyance mechanism provided in the vacuum conveyance chamber.

35. The contact forming system of claim 34, wherein the metal film forming apparatus forms the metal film by CVD or ALD.

36. A non-transitory computer-readable storage medium that stores a computer program for controlling an oxide film removing apparatus which, when executed, causes a computer to control the oxide film removing apparatus and execute the method of claim 1.

37. A non-transitory computer-readable storage medium that stores a computer program for controlling a contact forming system which, when executed, causes a computer to control the contact forming system and execute the contact forming method of claim 32.
